(19) United States
(12) Patent Application Publication
(10) Pub. No.: US 2025/0351397 A1
(43) Pub. Date: Nov. 13, 2025

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Tzu-Ging Lin, Kaohsiung City (TW); Ya-Yi sai, Hsinchu (TW); Yun-Chen Wu, Hsinchu (TW); Shu-Yuan Ku, Zhubei City (TW)

(21) Appl. No.: 19/276,057

(22) Filed: Jul. 22, 2025

Related U.S. Application Data
(63) Continuation of application No. 18/609,511, filed on Mar. 19, 2024.
(60) Provisional application No. 63/614,693, filed on Dec. 26, 2023.

(51) Int. Cl. H10D 30/01; H01L 21/768; H01L 23/535; H10D 30/43; H10D 30/67; H10D 62/10; H10D 64/01

(52) U.S. Cl. CPC H10D 30/014; H01L 21/76895; H01L 23/535; H10D 30/43; H10D 30/6735; H10D 62/121; H10D 64/017

(57) ABSTRACT

A method of forming a semiconductor device includes: forming a gate structure over a fin that protrudes above a substrate; forming an interlayer dielectric (ILD) layer over the fin around the gate structure; forming a first dielectric plug and a second dielectric plug in the gate structure on opposing sides of the fin to cut the gate structure into a plurality of discrete segments; forming a patterned mask layer over the ILD layer, where an opening of the patterned mask layer exposes a segment of the gate structure interposed between the first and the second dielectric plugs; etching, using the patterned mask layer as an etching mask, the segment of the gate structure to form a recess in the gate structure; extending the recess into the fin by performing an anisotropic etching process to deepen the recess; and after extending the recess, filling the recess with a dielectric material.

### PRIORITY CLAIM AND CROSS-REFERENCE

This application is a continuation of U.S. patent application Ser. No. 18/609,511, filed on Mar. 19, 2024 and entitled “Nanostructure Field-Effect Transistor Device and Methods of Forming,” which claims priority to U.S. Provisional Application No. 63/614,693, filed on Dec. 26, 2023 and entitled “CPODE Etch Profile Controlling for Back Side Power Rail Application,” which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A-5C, 6A-6C, 7A-7C, 8A, 8B, 9A, 9B, 10A, 10B, 11A, 11B, 12A, 12B, 13A-13C, 14A-14C, 15A, 15B, 16A, 16B, 17A, 17B, 18A, 18B, 19A, 19B, 20A, 20B, 21A, 21B, 22A-22C, 23A, 23B, 24A, 24B, 25A, 25B, 26A, and 26B are various views of a nanostructure field-effect transistor (NSFET) device at various stages of manufacturing, in accordance with an embodiment.

FIGS. 27A-27C illustrate photoresist peeling issue during patterning of a mask layer.

FIGS. 28A and 28B illustrate patterning of a mask layer, in some embodiments.

FIGS. 29A, 29B, 30A, 30B, 31A, 31B, 32A, 32B, 33A, 33B, 34A, 34B, 35A, 35B, 36A-36C, 37A, and 37B are various views of a nanostructure field-effect transistor (NSFET) device at various stages of manufacturing, in accordance with another embodiment.

FIGS. 38A and 38B illustrate bowing condition during an etching process.

FIGS. 39A and 39B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

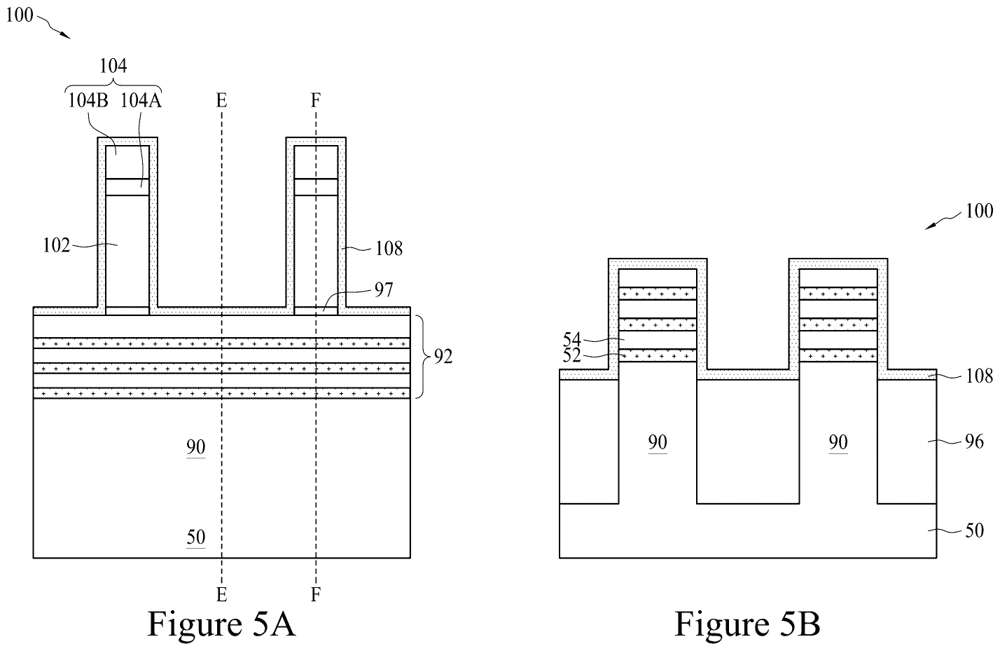

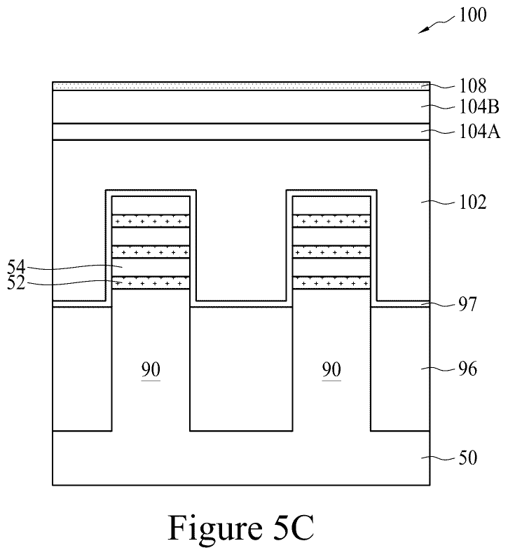

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIGS. 5A-5C) illustrate different views of the device at the same stage of processing.

Embodiments of the present disclosure are discussed in the context of forming nanostructure field-effect transistor (NSFET) devices (e.g., nanowire devices, nanosheet devices). The principles of the present disclosure can be applied to other types of devices, such as fin field-effect transistor (FinFET) devices.

In accordance with some embodiments, in order to avoid photoresist peeling issue in a Continuous Metal on Diffusion Edge (CMODE) process or a Continuous Poly on Diffusion Edge (CPODE) process, the location of the cut pattern in the photoresist layer is purposely shifted away from a center axis of the gate structure. However, shifting the location of the cut pattern may cause bowing issue for the opening formed under the cut pattern between gate spacers of the gate structure. The present disclosure solves the bowing issue by using an anisotropic etching process with lower etching selectivity to form the opening. The low etching selectivity reduces scattered ions/radicals during the etching to reduce asymmetric etching effect, thereby avoiding the bowing issue. Since the bowing condition may interfere with formation of backside vias formed subsequently to connect to backside power rails, the disclosed embodiments reduce device failure and improve production yield.

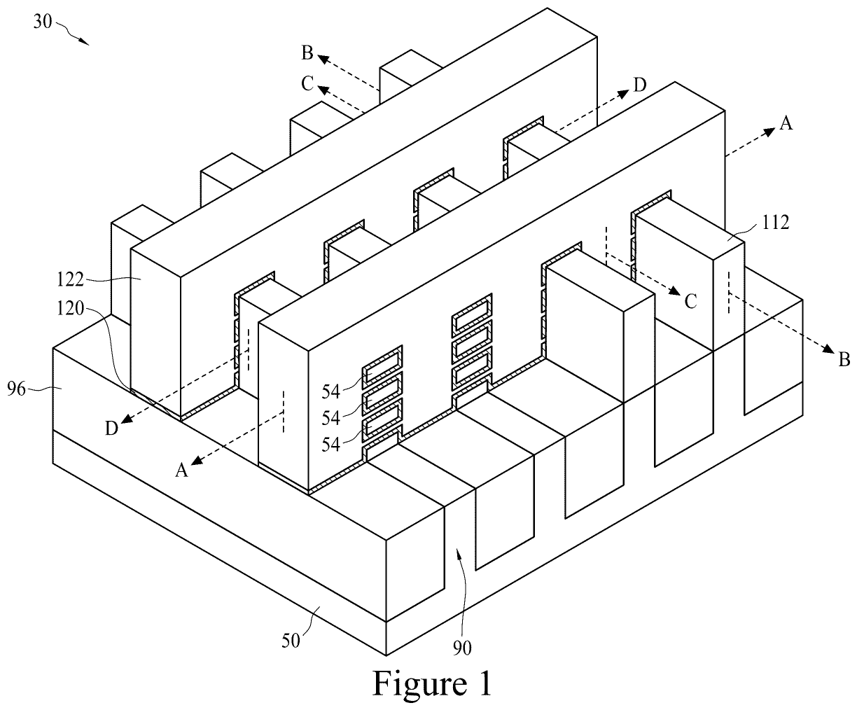

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

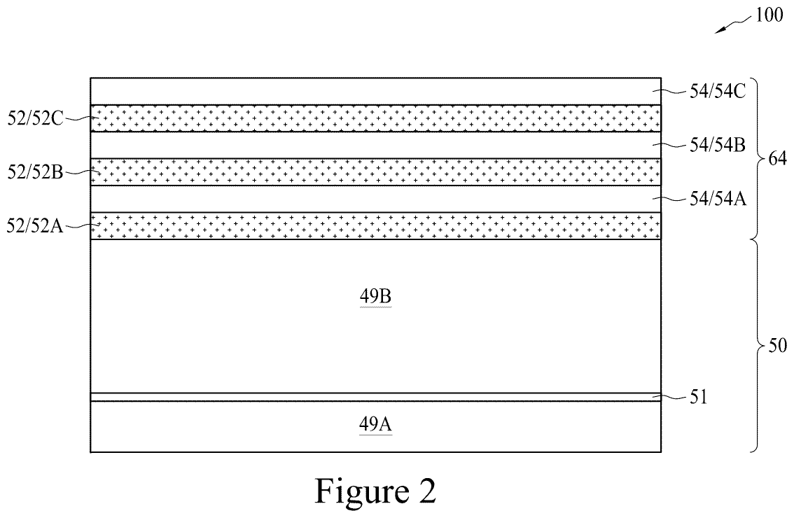

FIGS. 2, 3A, 3B, 4A, 4B, 5A-5C, 6A-6C, 7A-7C, 8A, 8B, 9A, 9B, 10A, 10B, 11A, 11B, 12A, 12B, 13A-13C, 14A-14C, 15A, 15B, 16A, 16B, 17A, 17B, 18A, 18B, 19A, 19B, 20A, 20B, 21A, 21B, 22A-22C, 23A, 23B, 24A, 24B, 25A, 25B, 26A, and 26B are various views (e.g., cross-sectional view, top view) of a nanostructure field-effect transistor (NSFET) device 100 at various stages of manufacturing, in accordance with an embodiment.

In FIG. 2, a substrate 50 is provided. In the example of FIG. 2, the substrate 50 comprises a lower substrate 49A and an upper substrate 49B, with an etch stop layer 51 sandwiched in between. In some embodiments, the lower substrate 49A and the upper substrate 49B are formed of a same or similar material, and therefore, may be collectively referred to as substrate 49 in the discussion herein. The substrate 49 may be a semiconductor substrate, such as a bulk semiconductor, a semiconductor-on-insulator (SOI) substrate, or the like, which may be doped (e.g., with a p-type or an n-type dopant) or undoped. The substrate 49 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 49 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the etch stop layer 51 is used to control a stopping point in a subsequent backside chemical mechanical planarization (CMP) process for thinning the substrate 50, and therefore, may also be referred to as a CMP stop layer 51. The etch stop layer 51 is formed of a different material than the substrate 49 to provide etching selectivity. For example, the substrate 49 (e.g., 49A and 49B) may be formed of silicon, and the etch stop layer 51 may be formed of silicon oxide, silicon nitride, or the like. The etch stop layer 51 may be formed by, e.g., ion implantation into the substrate 49, as an example. As another example, the substrate 49A may be formed by a suitable formation method (e.g., chemical vapor deposition (CVD), physical vapor deposition (CVD), or the like), then the etch stop layer 51 may be formed on the substrate 49A (e.g., using CVD, PVD, or the like). After the etch stop layer 51 is formed, the upper substrate 49B is formed on the etch stop layer 51 using any suitable formation method. In other embodiments, the etch stop layer 51 is omitted.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. The multi-layer stack 64 (which may also be referred to as an epitaxial material stack) will be patterned to form channel regions of an NSFET in subsequent processing. In particular, the multi-layer stack 64 will be patterned and etched to form horizontal nanostructures (e.g., nanosheets or nanowires), with the channel regions of the resulting NSFET including multiple horizontal nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed. Although semiconductor materials (e.g., silicon, silicon germanium) are used in the above example to form the layer stack 64, the above example is illustrative and non-limiting. For example, in embodiments where the layers labeled as 52 are removed subsequently to release the second semiconductor material 54 to form nanostructures (e.g., nanosheets, or nanowires), the layers labeled as 52 may be referred to as interposer layers and may be formed of a suitable material, e.g., silicon oxide.

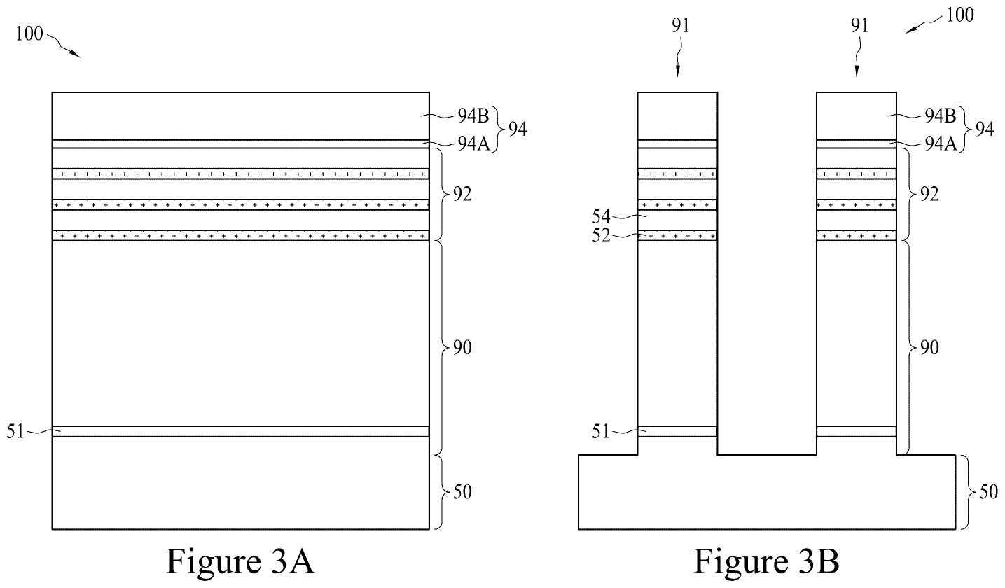

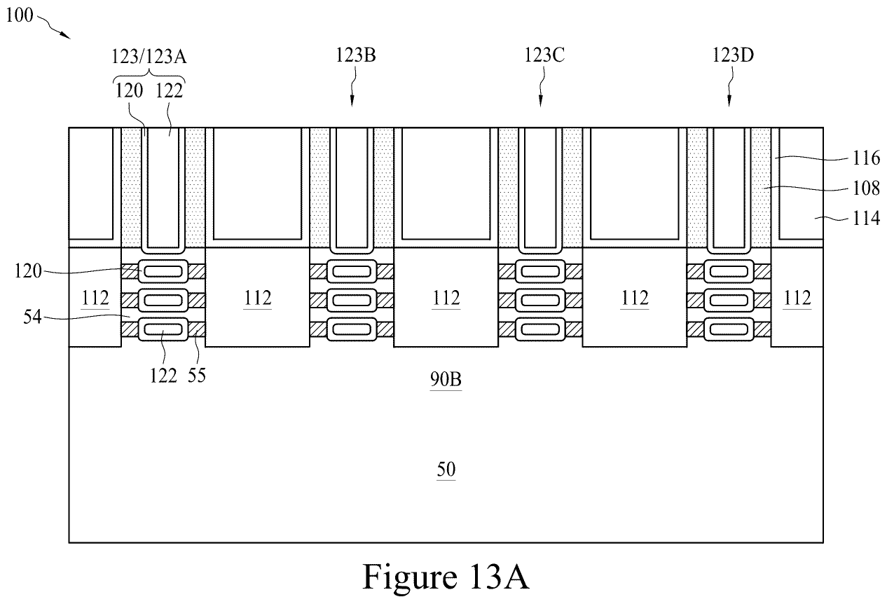

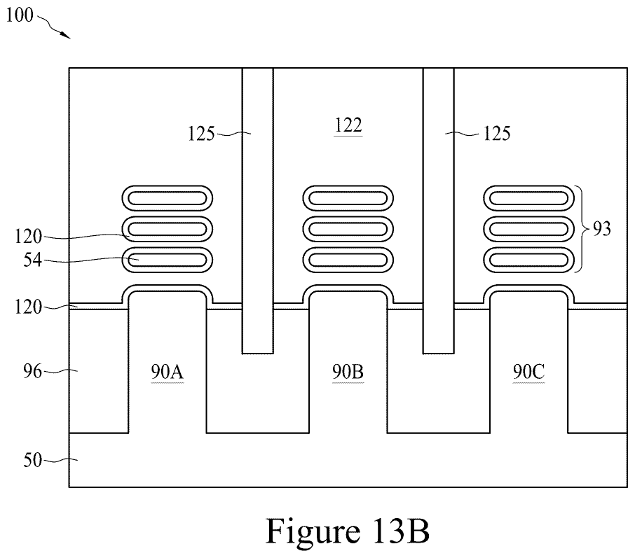

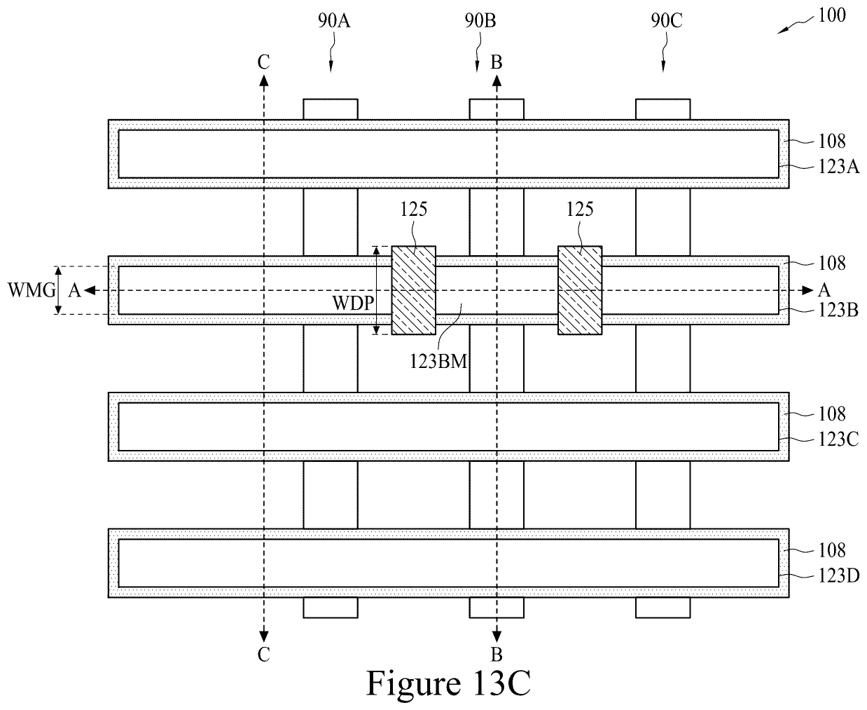

FIGS. 3A, 3B, 4A, 4B, 5A-5C, 6A-6C, 7A-7C, 8A, 8B, 9A, 9B, 10A, 10B, 11A, 11B, 12A, 12B, 13A-13C, 14A-14C, 15A, 15B, 16A, 16B, 17A, 17B, 18A, 18B, 19A, 19B, 20A, 20B, 21A, 21B, 22A-22C, 23A, 23B, 24A, 24B, 25A, 25B, 26A, and 26B are various views (e.g., cross-sectional view, top view) of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, and 26A are cross-sectional views along cross-section B-B in FIG. 1. FIGS. 3B, 4B, 5C, 6C, 7C, 8B, 9B, 10B, 11B, 12B, 13B, 14B, 15B, 16B, 17B, 18B, 19B, 20B, 21B, 22B, 23B, 24B, 25B, and 26B are cross-sectional views along cross-section A-A in FIG. 1. FIGS. 5B, 6B, and 7B are cross-sectional views along cross-section D-D in FIG. 1. FIGS. 13C, 14C, and 23C are top views (e.g., plan views) of the NSFET device 100. The number of fins and the number of gate structures illustrated in the figures are merely a non-limiting example, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90, as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material(s) as the substrate 50. In the illustrated embodiment of FIG. 2, the fin 90 includes materials of the etch stop layer 51, the upper substrate 49B, and the lower substrate 49A. For simplicity, the etch stop layer 51 may not be shown in all of the subsequent figures, with the understanding the etch stop layer 51 may be formed in the fin 90.

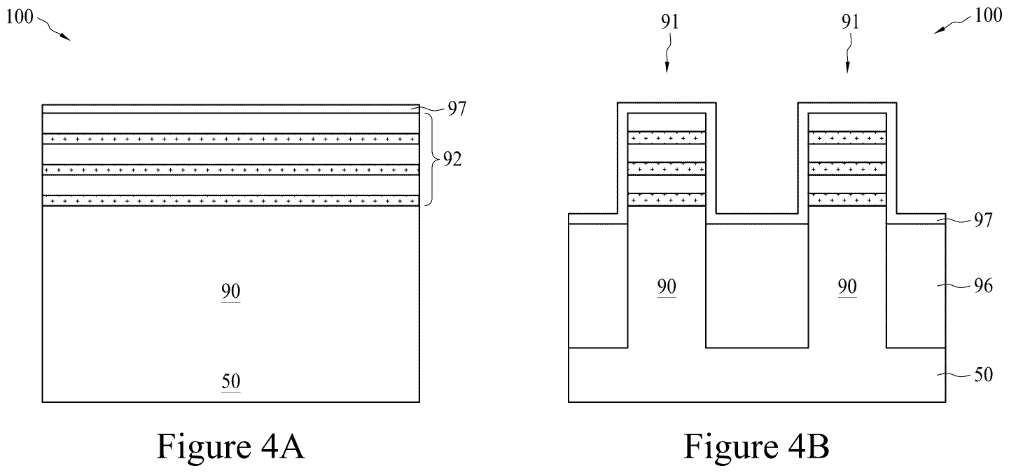

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, in FIGS. 5A-5C, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure, in some embodiments.

Next, a gate spacer layer 108 is formed by conformally depositing an insulating material over the layer stacks 92, the STI regions 96, and the dummy gates 102. The insulating material may be silicon oxide, silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections D-D and A-A in FIG. 1, respectively.

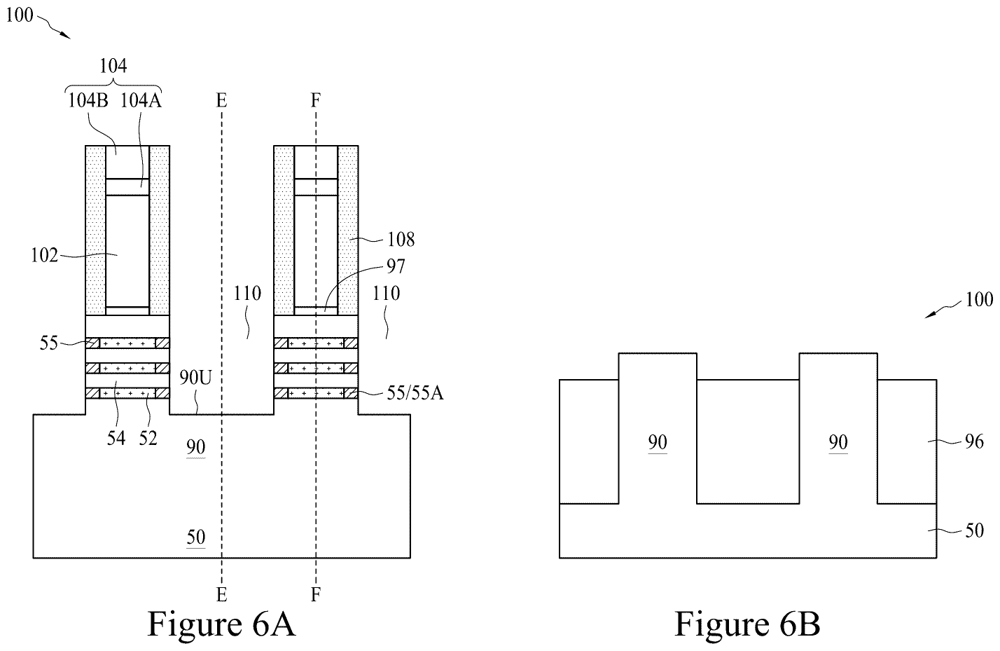

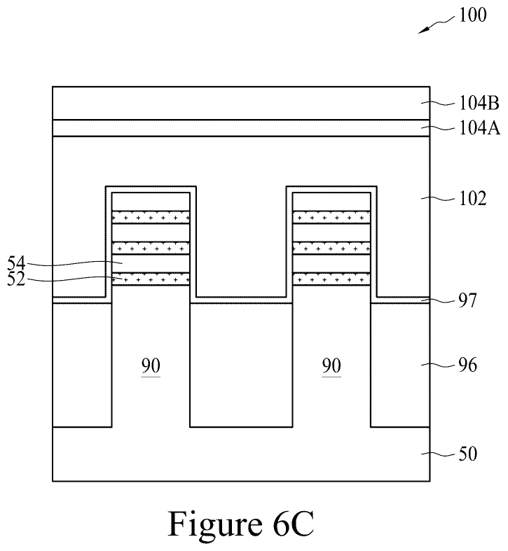

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gates 102 and the dummy gate dielectric 97) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, formed by a suitable deposition method such as PVD, CVD, atomic layer deposition (ALD), or the like. Next, an etching process, such as an anisotropic etching process, is performed to remove portions of the inner spacer layers disposed outside the sidewall recesses of the first semiconductor material 52. The remaining portions of the inner spacer layers (e.g., portions disposed inside the sidewall recesses of the first semiconductor material 52) form inner spacers 55. As illustrated in FIG. 6A, the openings 110 expose sidewalls of the second semiconductor material 54 and expose an upper surface 90U of the fin 90.

FIGS. 6B and 6C illustrate cross-sectional views of the NSFET device 100 in FIG. 6A along cross-sections E-E and F-F, respectively. In FIG. 6B, the portions of the gate spacer layer 108 disposed on the upper surface of the STI regions 96 between neighboring fins 90 are completely removed by the anisotropic etching process used for forming the gate spacers 108. In some embodiments, portions of the gate spacer layer 108 are left (e.g., remain) between neighboring fins 90 on the upper surface of the STI regions 96. Those portions of the gate spacer layer 108 may be left because the anisotropic etching process discussed above may not completely remove the gate spacer layer 108 disposed between neighboring fins 90, due to the small distance between the neighboring fins 90 reducing efficiency of the anisotropic etching process.

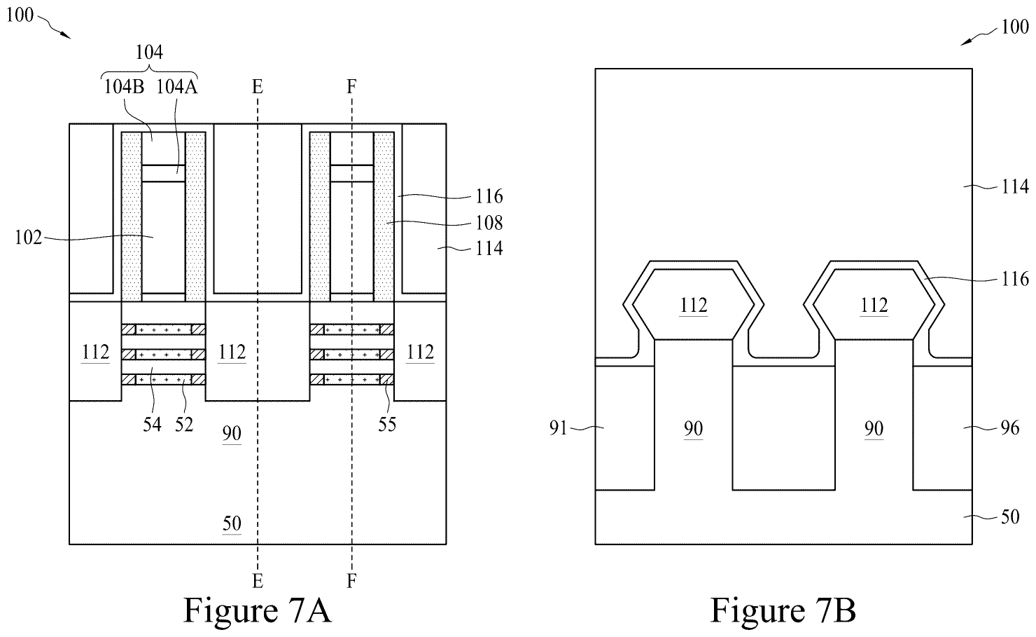

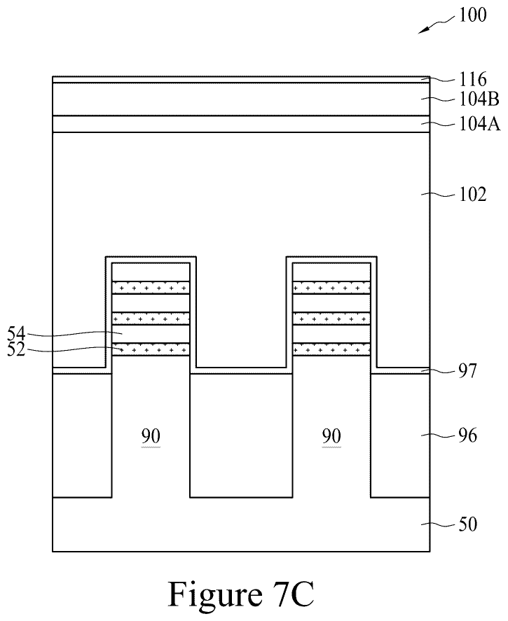

Next, in FIGS. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7B) after the epitaxy process is completed. In other embodiments, these facets cause adjacent epitaxial source/drain regions 112 of a same NSFET to merge.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, plasma-enhanced CVD (PECVD), or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used. FIGS. 7B and 7C illustrate cross-sectional views of the NSFET device 100 of FIG. 7A, but along cross-section E-E and F-F in FIG. 7A, respectively.

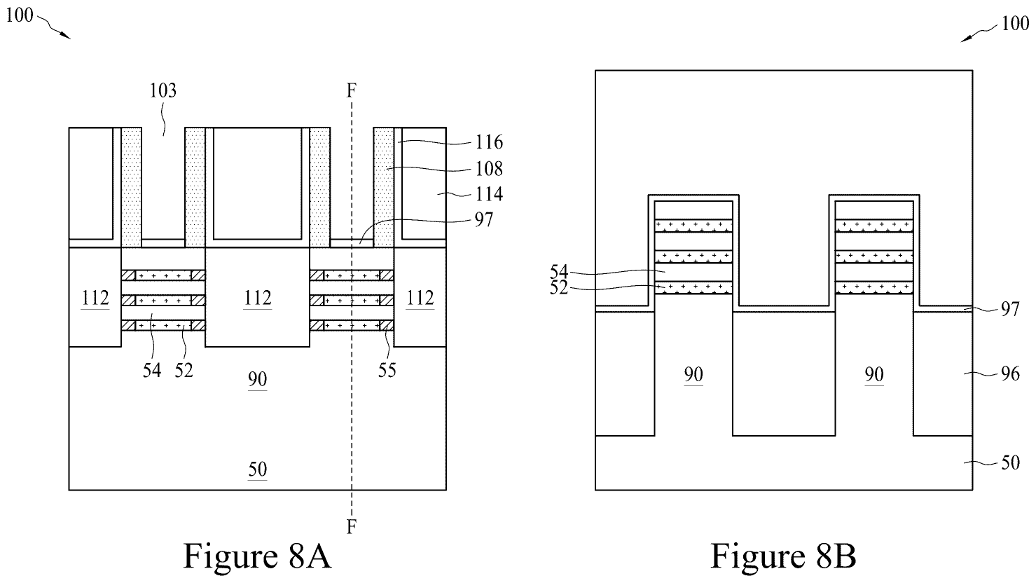

FIGS. 8A, 8B, 9A, 9B, 10A, 10B, 11A, 11B, 12A, and 12B illustrate a replacement gate process where the dummy gate structures (e.g., 102 and 97) are removed and replaced by replacement gate structures 123 (e.g., metal gate structures).

Next, in FIGS. 8A and 8B, the dummy gates 102 are removed. To remove the dummy gates 102, a planarization process, such as a CMP, is performed to level the top surfaces of the first ILD 114 and CESL 116 with the top surfaces of the dummy gates 102 and gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102 are exposed through the first ILD 114.

Next, the dummy gates 102 are removed in an etching step(s), so that recesses 103 are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102. FIG. 8B illustrates the cross-sectional view of the NSFET device 100 of FIG. 8A along the cross-section F-F.

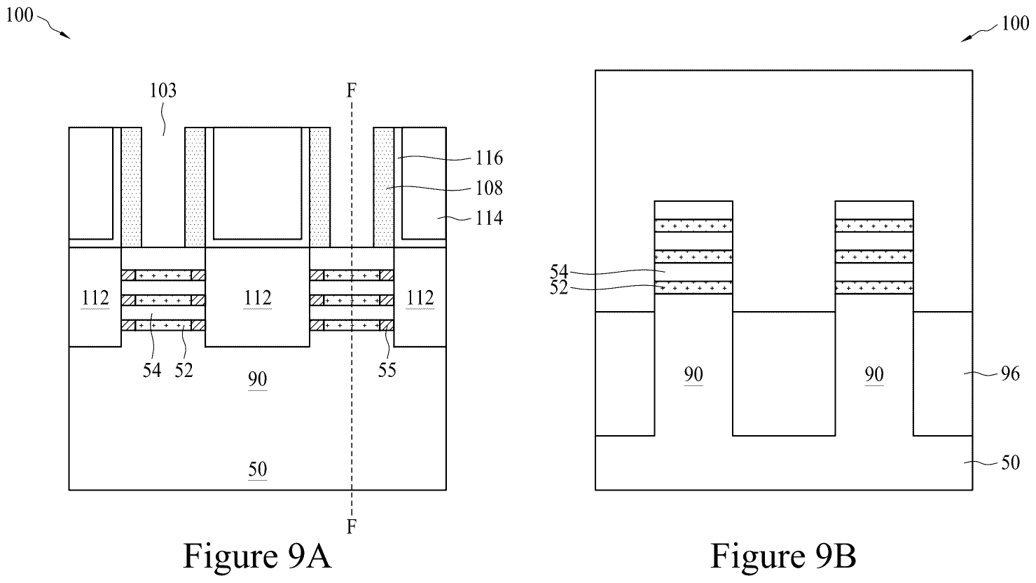

Next, in FIGS. 9A and 9B, the dummy gate dielectric 97 in the recesses 103 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 9A and 9B, each recess 103 exposes a channel region of the NSFET. Each channel region is disposed between neighboring pairs of the epitaxial source/drain regions 112.

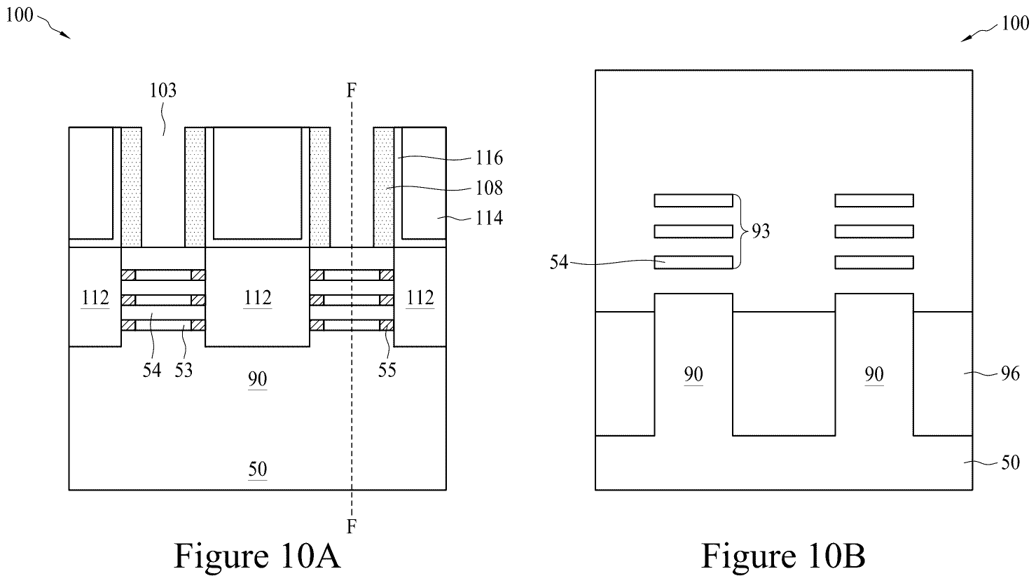

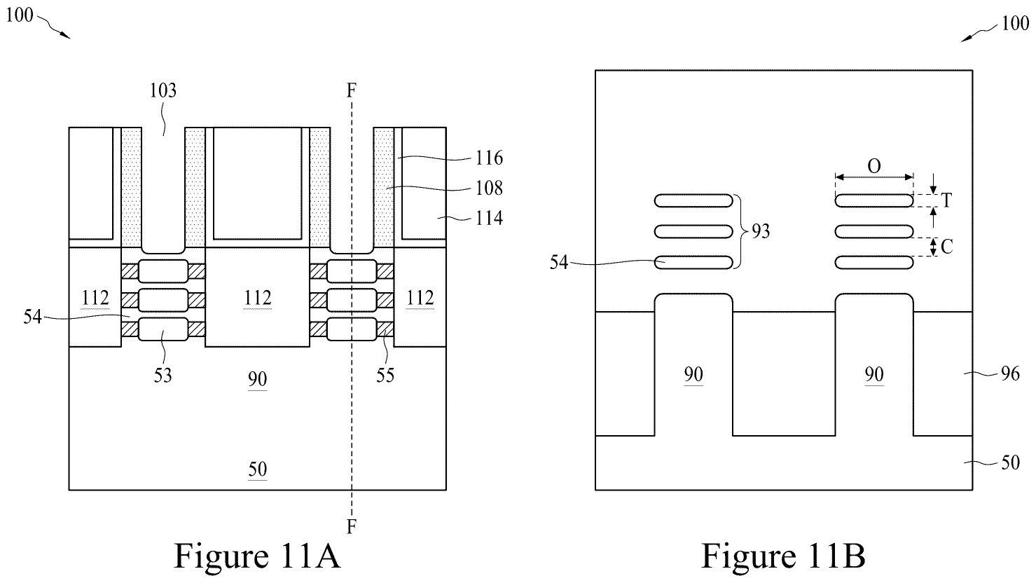

Next, in FIGS. 10A and 10B, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100 formed. As illustrated in FIG. 10A, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas, where the etching gas comprises F₂ and HF, and the carrier gas may be an inert gas such as Ar, He, N₂, combinations thereof, or the like, in some embodiments.

FIG. 10A illustrates the cross-sectional view of the NSFET device 100 along a longitudinal axis of the fin (e.g., along a current flow direction in the fin), and FIG. 10B illustrates the cross-sectional view of the NSFET device 100 along cross-section F-F, which is a cross-section along a direction perpendicular to the longitudinal axis of the fin and across a middle portion of the nanostructure 54.

As illustrated in FIG. 10A, each of the nanostructures 54 has a rectangular shaped cross-section along the longitudinal axis of the fin. Similarly, in FIG. 10B, in a cross-section along a direction perpendicular to the longitudinal axis of the fin and across a middle portion of the nanostructure 54, each of the nanostructures 54 has a rectangular shaped cross-section.

Next, in FIGS. 11A and 11B, the nanostructures 54 are reshaped by a nanostructure reshaping process (e.g., an isotropic etching process). In some embodiments, the nanostructures 54 are reshaped by a selective etching process using an etchant that is selective to the material of the nanostructures 54 (e.g., the second semiconductor material 54), such that the nanostructures 54 are etched without substantially attacking other materials in the NSFET device 100, such as oxide, silicon nitride, and low-K dielectric materials.

In some embodiments, the isotropic etching process (e.g., a selective etching process) to reshape the nanostructures 54 is performed using an etching gas, and optionally, a carrier gas, where the etching gas comprises F₂ and NH₃, and the carrier gas may be an inert gas such as Ar, He, N₂, combinations thereof, or the like.

Besides using a mixture of F₂ and NH₃ as the etching gas, other suitable etching gases, such as ClF₃, or a mixture of NF₃ and NH₃, may alternatively be used as the etching gas to reshape the nanostructures 54. For example, an isotropic etching process (e.g., an isotropic plasma etching process) using an etching gas comprising NF₃ and NH₃ may be performed to reshape the nanostructures 54.

The nanostructure reshaping process thins the middle portion of each nanostructure 54 while the end portions of the nanostructure 54 remain substantially unchanged, thus generating a dumbbell shaped cross-section for the nanostructure 54 in FIG. 11A. In addition, the nanostructure re-shaping process removes the sharp edges (e.g., see the 90-degree corners of the nanostructures 54 in FIG. 10B) of the nanostructures 54, thus generating rounded edges for each nanostructure 54 (see the rounded corners of each nanostructure 54 in FIG. 11B), as described in more details below.

As illustrated in FIG. 11A, after the nanostructure reshaping process, in the cross-section along the longitudinal axis of the fin, each of the nanostructures 54 has a dumbbell shape, where end portions of the nanostructure 54 (e.g., portions physically contacting the source/drain regions 112) have a thickness (measured along the vertical direction of FIG. 11A) larger than that of the middle portion (e.g., a portion mid-way between the end portions). In some embodiments, a difference between the thicknesses of the end portion of the nanostructure 54 and the middle portion of the nanostructure 54 is between about 0 nm and about 3 nm. In the example of FIG. 11A, the upper surface and the lower surface of the middle portion of each nanostructure 54 are illustrated as level surfaces (e.g., flat surfaces). This is, of course, merely a non-limiting example. In some embodiments, the upper surface and lower surface of the middle portion of each nanostructure 54 are curved, such as curved toward a horizontal center axis of the nanostructure 54. In addition, in the cross-section of FIG. 11B, each of the nanostructures 54 has a stadium shape (may also be referred to as a racetrack shape, a discorectangle shape, an obround shape, or a sausage body shape). In particular, in the cross-section of FIG. 11B, the corners of each nanostructure 54 are rounded (e.g., curved). In some embodiments, a thickness T (also referred to as sheet thickness) of the nanostructure 54 (e.g., nanosheet) is between about 6.3 nm and about 8.2 nm, with a mean value (e.g., average value) of about 7.1 nm. A spacing C (also referred to as sheet-to-sheet distance) between adjacent nanostructures 54 is between about 4.5 nm and about 5.9 nm, with a mean value of about 5.2 nm, in some embodiments. A width O (also referred to as sheet width) of the nanostructure 54 is between about 94.9 nm and about 97.5 nm, with a mean value of about 96.2 nm, in some embodiments.

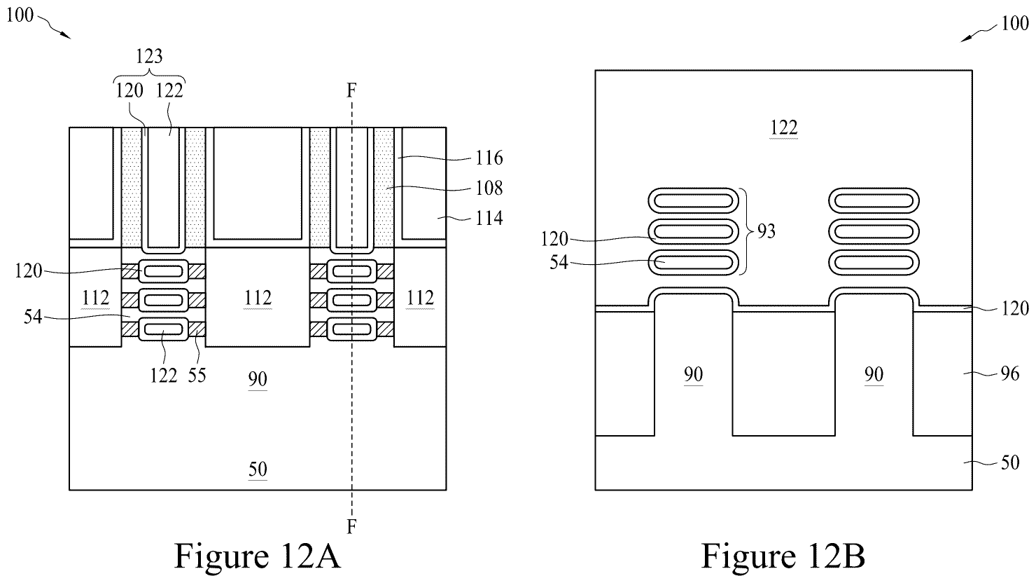

As feature sizes continue to shrink in advanced processing nodes, the distance between adjacent nanostructures 54 may become so small that it may be difficult to form layers (e.g., gate dielectric layer, work function layers) around the nanostructures 54 in subsequent processing. By reshaping the nanostructures 54, e.g., thinning the middle portions of the nanostructures 54, the distance between adjacent nanostructures 54 is increased, thus making it easier to form, e.g., gate dielectric layer 120 (see FIGS. 12A and 12B) around the nanostructures 54. In addition, since the thickness T of the nanostructures 54, which form the channel regions 93 of the NSFET device 100, is reduced by the nanostructure reshaping process, it is easier to control (e.g., turning on or off) the NSFET device 100 by applying a gate control voltage on the metal gate formed in subsequent processing.

In some embodiments, the nanostructure reshaping process illustrated in FIGS. 11A and 11B is omitted. In subsequent figures, the channel regions 93 of the NSFET device 100 are illustrated as having the cross-sections of FIGS. 11A and 11B, with the understanding that the channel regions 93 may have the cross-sections of FIGS. 10A and 10B (e.g., when the nanostructure reshaping process is omitted).

Next, in FIGS. 12A and 12B, gate dielectric layers 120 and gate electrodes 122 are formed to form replacement gates. The gate dielectric layers 120 are deposited conformally in the recesses 103, such as on the top surfaces and the sidewalls of the semiconductor fin 90, and on sidewalls of the gate spacers 108. The gate dielectric layers 120 may also be formed on the top surface of the first ILD 114. Notably, the gate dielectric layers 120 are formed to wrap around the nanostructures 54. In accordance with some embodiments, the gate dielectric layers 120 comprise silicon oxide, silicon nitride, or multilayers thereof. In some embodiments, the gate dielectric layers 120 are formed of a high-k dielectric material, and in these embodiments, the gate dielectric layers 120 may have a k value greater than about 7.0, and may include a metal oxide or a silicate of Hf, Al, Zr, La, Mg, Ba, Ti, or Pb, or combinations thereof. The formation methods of the gate dielectric layers 120 may include Molecular-Beam Deposition (MBD), ALD, PECVD, and the like.

Next, the gate electrodes 122 are deposited over and around the gate dielectric layers 120, and fill the remaining portions of the recesses 103. The gate electrodes 122 may include a metal-containing material such as TiN, TiO, TaN, TaC, Co, Ru, Al, W, combinations thereof, or multi-layers thereof. For example, although a single layer gate electrode 122 is illustrated, the gate electrode 122 may comprise any number of liner layers (e.g., barrier layers), any number of work function tuning layers, and a fill metal material. After the filling of the gate electrodes 122, a planarization process, such as a CMP, may be performed to remove the excess portions of the gate dielectric layers 120 and the material of the gate electrodes 122, which excess portions are over the top surface of the first ILD 114. The remaining portions of material of the gate electrodes 122 and the gate dielectric layers 120 thus form replacement gates of the resulting NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

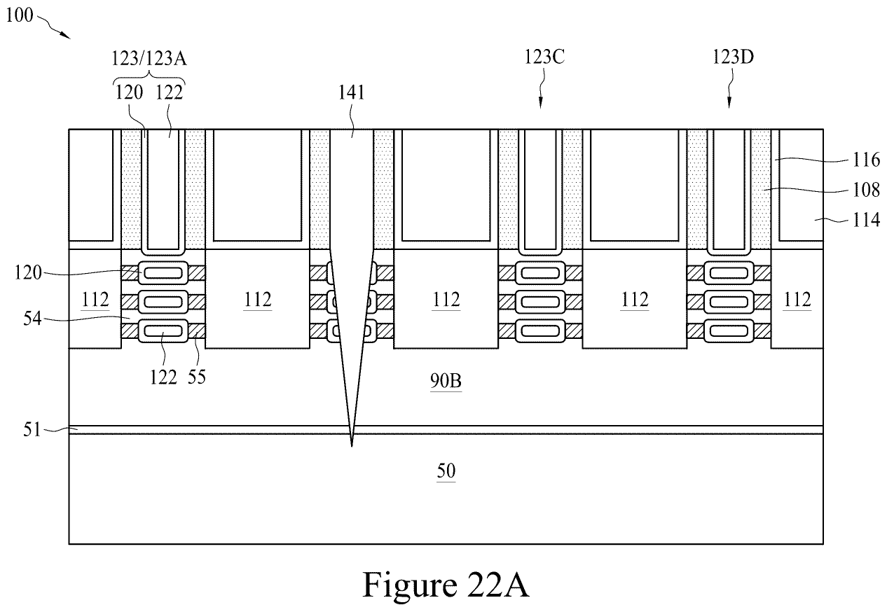

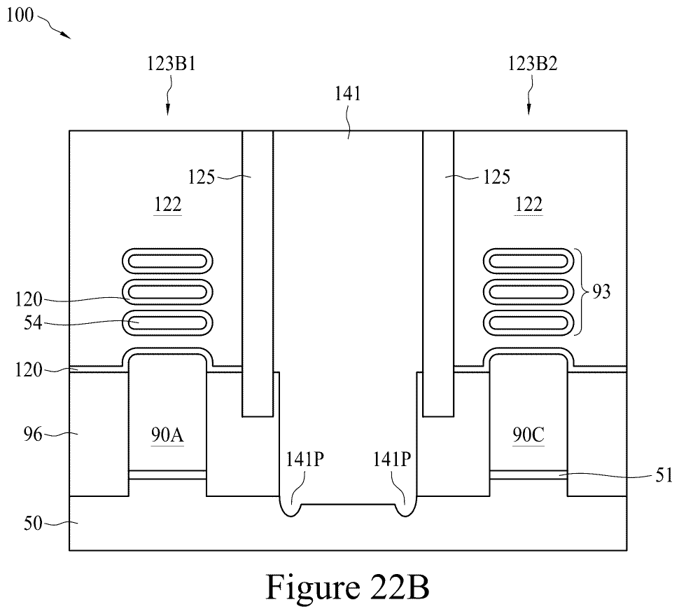

Next, the formation process proceeds to the cutting of gate structures 123 and the cutting (e.g., removing) of some nanostructures 54 in order to form isolated transistors. The cutting of gate structure 123 is referred to as a Cut Metal Gate (CMG) process. The cutting of nanostructures 54 (and portions of their respective underlying fins 90) is referred to as a Continuous Metal On-Diffusion Edge (CMODE) process, or sometimes referred to as a Cut Metal on-Diffusion Edge (CMODE) process. Note that in the illustrated CMODE process, the cutting of nanostructures 54 and their respective underlying fins 90 is performed after the formation of replacement gate stacks 123. In the illustrated CMG process and CMODE process, some examples of the cutting positions are illustrated, as shown in FIGS. 13C and 22C. It is appreciated that the cutting processes may be performed at different positions and with different sizes, depending on the design of the transistors.

In FIGS. 12A and 12B, two fins 90 and two gate structures 123 are illustrated. This is, of course, a non-limiting example. The number of fins 90 and the number of gate structures 123 in the NSFET device 100 may be any suitable number. In subsequent figures (e.g., FIGS. 13A-26B), to facilitate discussion of the CMG process and CMODE process, three fins 90 (which are labeled as 90A, 90B, and 90C) and four gate structures 123 (which are labeled as 123A, 123B, 123C, and 123D) are illustrated.

Referring next to FIGS. 13A-13C, dielectric plugs 125 are formed to cut the gate structure 123B into a plurality of separate segments. FIG. 13C shows the top view (e.g., a plan view) of the NSFET device 100 after the dielectric plugs 125 are formed. For simplicity, not all features of the NSFET device 100 are illustrated in FIG. 13C. For example, FIG. 13C only shows the fins 90A, 90B, 90C (may be collectively referred to as fins 90), the gate structures 123A, 123B, 123C, and 123D (may be collectively referred to as gate structures 123), gate spacers 108 around the sidewalls of the gate structures 123, and the dielectric plugs 125.

In some embodiments, the dielectric plugs 125 are formed by forming openings in the gate structure 123B and the first ILD 114 (e.g., using photo lithography and etching techniques), and filling the openings with a dielectric material, such as silicon nitride, silicon oxide, combinations thereof, or the like. Next, a planarization process, such as CMP, may be performed to remove excess portions of the dielectric material from the upper surface of the first ILD 114, and the remaining portions of the dielectric material in the openings form the dielectric plugs 125.

In the illustrated example, the dielectric plugs 125 are formed on opposing sides of the fin 90B. For example, in FIG. 13C, one of the dielectric plugs 125 is formed between the fins 90A and 90B, and another one of the dielectric plugs 125 is formed between the fins 90B and 90C. A dimension WDP of the dielectric plug 125, measured along the direction of cross-section B-B, is larger than a dimension WMG of the gate structure 123B to ensure that the dielectric plug 125 cuts the gate structure 123B into separate segments that are electrically isolated from each other, in the illustrated embodiment. As shown in FIG. 13B, the dielectric plugs 125 extend through the gate structure 123 and into the STI regions 96 to ensure separation of the different segments of the gate structure 123B. The dielectric plugs 125 are used to protect segments of the gate structure 123B not intended for removal during a subsequent etching process to remove a segment 123BM (see FIG. 13C) of the gate structure 123, in some embodiments. Note that the dielectric plugs 125 are not in the cross-section B-B of FIG. 13C, thus are not visible in FIG. 13A. In some embodiments, the dielectric plugs 125 are omitted, because the subsequent etching process performed to remove the segment 123BM (see FIG. 13C) of the gate structure 123B is anisotropic and therefore, is unlikely to damage other segments of the gate structure 123B.

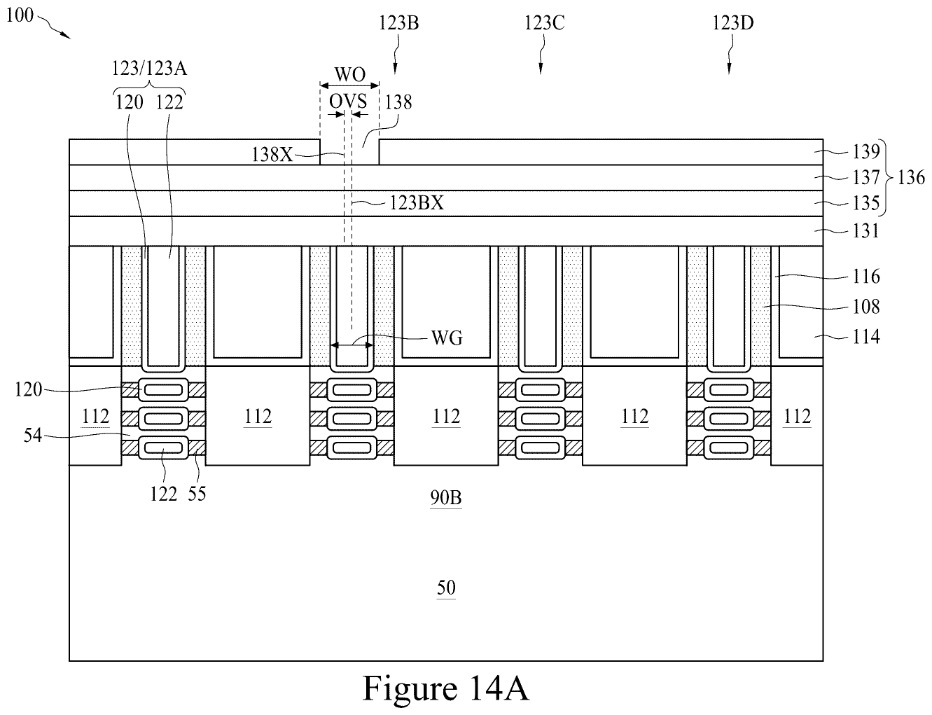

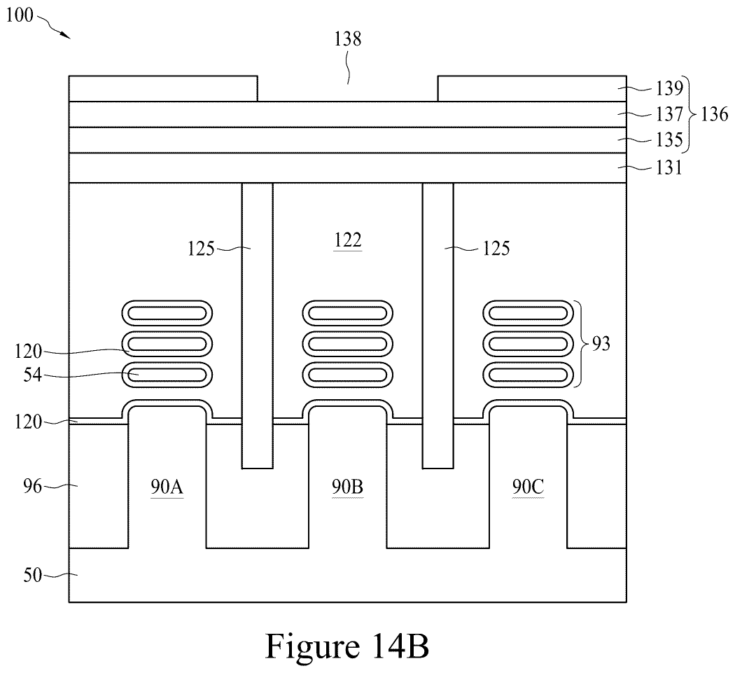

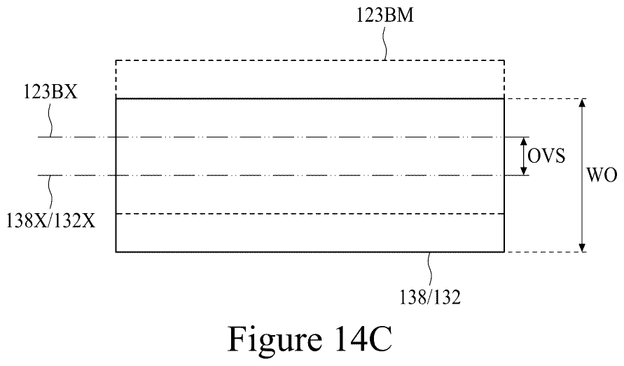

Next, in FIGS. 14A and 14B, a hard mask layer 131 (may also be referred to as a mask layer 131) is formed over the first ILD 114 and the gate structures 123. The hard mask layer 131 may be a single-layer hard mask formed of, e.g., silicon nitride, silicon oxynitride, or the like, using a suitable formation method such as CVD. In some embodiments, the hard mask layer 131 has a multi-layered structure. For example, the hard mask layers 131 may include a silicon layer sandwiched between two silicon nitride layers.

Next, an etching mask 136 is formed over the hard mask layer 131. The etching mask 136 may have a single-layered structure (which may be a photoresist layer), or a dual-layered structure including a Bottom Anti-reflective Coating (BARC) layer and a photoresist layer. In the example of FIGS. 14A and 14B, the etching mask 136 has a tri-layered structure, which includes a bottom layer 135 (e.g., a carbon based BARC layer), a middle layer 137 (e.g., a silicon oxide layer, a silicon nitride layer, or a silicon oxynitride layer), and a photoresist layer 139.

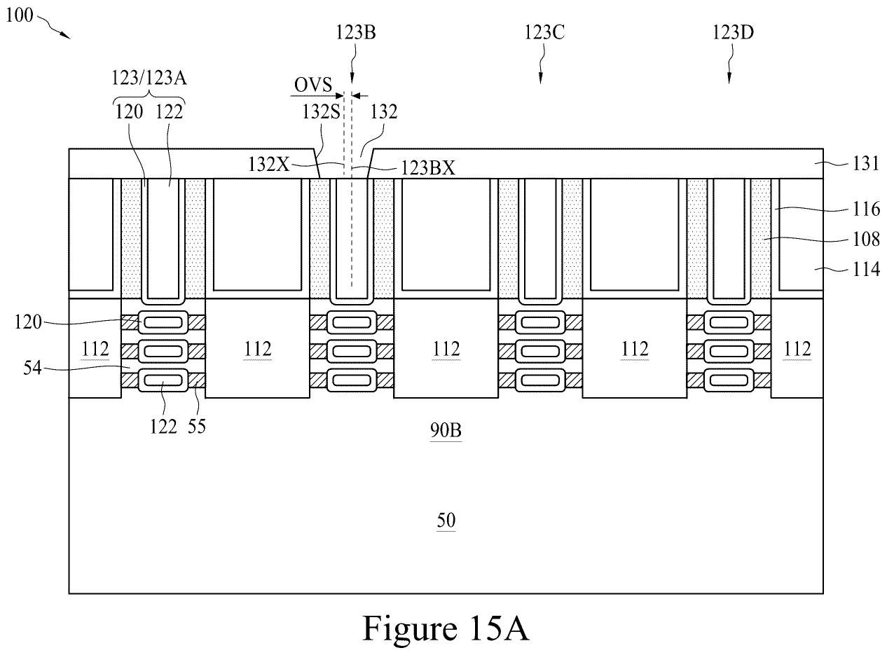

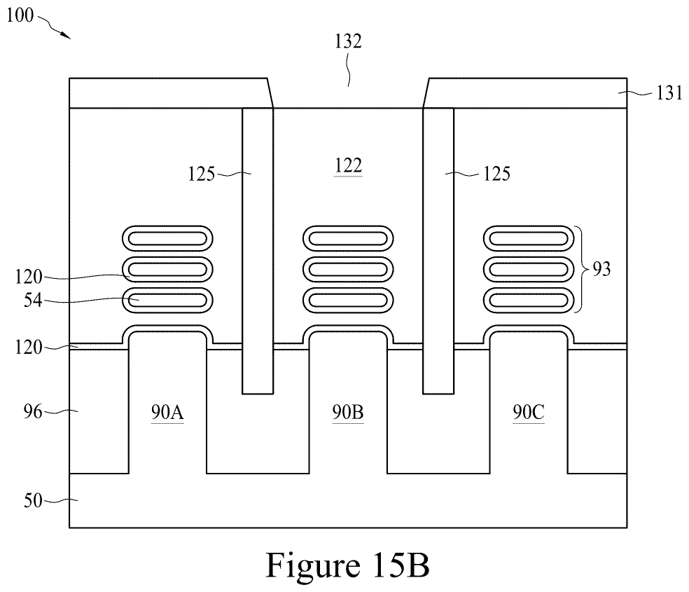

Next, an opening 138 is formed in the photoresist layer 139 of the etching mask 136. As will be discussed below, the opening 138 is transferred to the hard mask layer 131, and therefore, determines the location of an opening 132 (see FIGS. 15A and 15B) in the hard mask layer 131. The openings 132 in the hard mask layer 131 exposes a segment 123BM (see FIG. 13C) of the gate structure 123B disposed between the dielectric plugs 125 in FIG. 13C. While it may seem intuitive that the optimal location of the opening 138 should be directly over, and overlapping (e.g., overlaps completely in a top view), the segment 123BM of the gate structure 123B, the opening 138 in the present disclosure is purposely (e.g., intentionally) formed to be shifted away from that seemingly optimal location. In the example of FIG. 14A, the opening 138 has a lateral offset OVS between a center axis 138X of the opening 138 and a center axis 123BX of the gate structure 123B. FIG. 14C illustrates the top view of the NSFET device 100, in an embodiment. For clarity, FIG. 14C only illustrate boundaries of the opening 138 (illustrated as a rectangle), the center axis 138X of the opening 138, boundaries of the segment 123BM of the gate structure 123B (illustrated as a dashed rectangle), and the center axis 123BX of the gate structure 123B. Except for a lateral shift, the dashed rectangle and the rectangle in FIG. 14C are the same. The lateral offset OVS between the center axis 138X and the center axis 123BX is illustrated in FIG. 14C. Since the opening 138 is transferred to the hard mask layer 131 as the opening 132, the rectangle of the opening 138 also illustrates the opening 132 in the hard mask layer 131, in some embodiments. As illustrated in FIG. 14C, the opening 138 (or the opening 132) is formed to be laterally shifted from the segment 123BM of the gate structure 123B by a predetermined distance (e.g., the lateral offset OVS). As discussed below, the lateral offset OVS is used to reduce or avoid photoresist peeling issue.

Referring to FIG. 14A, denote the width of the opening 138 as WO, the lateral offset OVS may be between about 5% to about 33%, such as between about 10% and about 33%, or between about 20% and about 30%, of the width WO of the opening 138, in some embodiments. FIG. 14A also illustrates the width WG of the gate structure 123B, measured between the gate spacers 108 on opposing sides of the gate structure 123B. The width WO of the opening 138 may be the same as or similar to the width WG of the gate structure 123B.

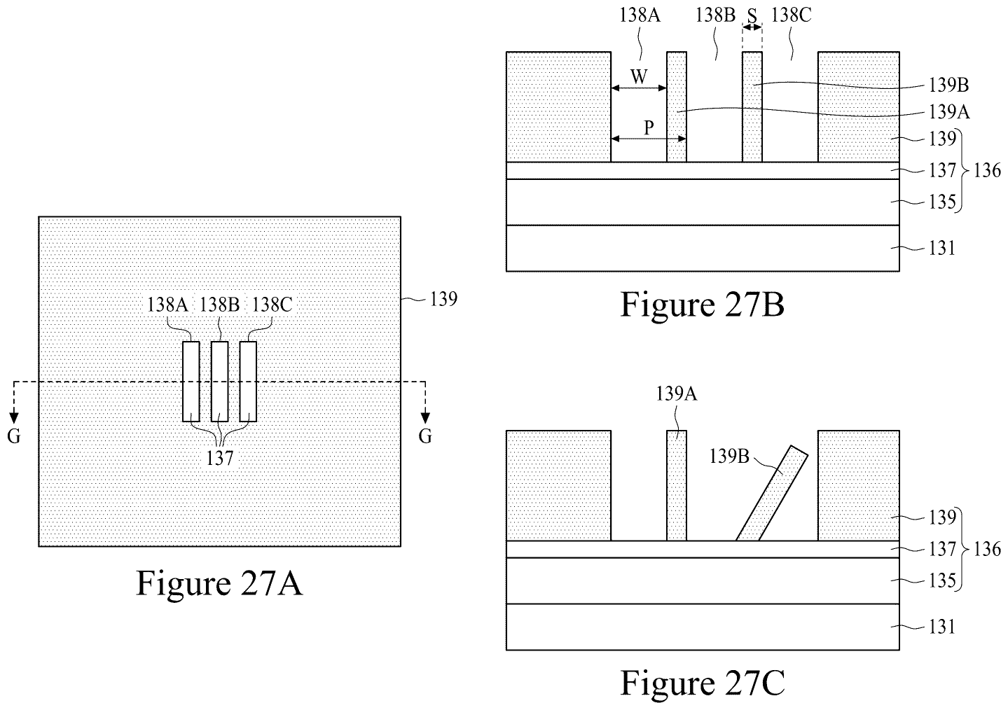

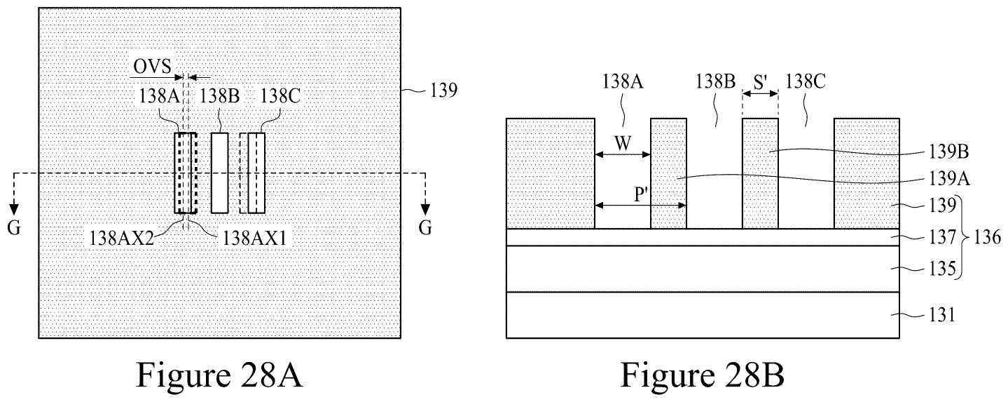

In some embodiments, the openings 138 is purposely (e.g., intentionally) formed to have the lateral offset OVS to avoid the photoresist peeling issue, as discussed below with reference to FIGS. 27A-27C and 28A-28B.

Referring temporarily to FIGS. 27A and 27B, which illustrate a top view and a cross-section view, respectively, of a tri-layered etching mask 136 and a hard mask layer 131, which correspond to the etching mask 136 and the hard mask layer 131 in FIGS. 14A and 14B. FIG. 27B shows the cross-sectional view along cross-section G-G in FIG. 27A. Note that FIG. 27A illustrates three openings 138A, 138B, and 138C (collectively referred to as openings 138) in the photoresist layer 139 in order to illustrate the reason and the advantage of having the lateral offset OVS. In FIGS. 14A and 14B, as well as other relevant figures of the illustrated embodiments, only one opening 138 is illustrated for simplicity, with the understanding that multiple openings 138, same as or similar to those illustrated in, e.g., FIGS. 28A, may be formed in the photoresist layer 139. For example, the opening 138A in FIG. 28A may correspond to the opening 138 in FIG. 14A.

In the example of FIG. 27B, the photoresist layer 139 includes two thin, fin shaped slices 139A and 139B disposed between the opening 138A and 138C. In FIG. 27B, the width of the fin shaped slices 139A and 139B is denoted as width S (also referred to as spacing of the openings), the width of the openings 138 is denotes as width W (also referred to adjacent critical dimension (CD) of the openings), and the pitch between adjacent openings 138 is denoted as pitch P. In semiconductor manufacturing processes, the feature sizes continue to shrink. Currently, feature sizes are in the order of nanometers in advanced processing nodes. Due to its dimension (e.g., small width S, and/or high aspect ratio), the fin shaped slices 139A and 139B may collapse. FIG. 27C illustrates an example where the fin shaped slice 139B of the photoresist layer 139 collapses, which is referred to as photoresist peeling issue. Photoresist peeling issue tends to happen when the width W is much larger than the width S (e.g., W>>S). Therefore, if the openings 138A is shifted to the left side of FIG. 27B and the openings 138C is shifted to the right side of FIG. 27B while the location of the opening 138B remain unchanged, the width S of the fin shaped slices 139A and 139B is increased and the likelihood of photoresist peeling issue happening is reduced. In general, the photoresist peeling issue may be avoided if the width W is less than or equal to half of the pitch size P (e.g., W≤½ P). This condition may be satisfied by shifting the location of the opening 138A and 138C as discussed above.

FIGS. 28A and 28B illustrate the effect of shifting the locations of the openings 138A and 138C as discussed above. In FIG. 28A, the location of 138B remains the same as in FIG. 27A, whereas the locations of the openings 138A and 138C have been shifted to the left side and right side, respectively, compared with the locations of the openings 138A and 138C in FIG. 27A. For comparison, the locations of the openings 138A and 138C in FIG. 27A are illustrated in dashed lines (e.g., as dashed rectangles) in FIG. 28A.

As illustrated in FIG. 28A, there is a lateral offset OVS between the center axis 138AX2 of the opening 138A in FIG. 28A and the center axis 138AX1 of the opening 138A in FIG. 27A (shown as a dashed rectangle in FIG. 28A). In some embodiments, the dashed rectangle in FIG. 28A, which illustrates the opening 138A in FIG. 27A, corresponds to (e.g., overlaps completely with) the boundaries of the segment 123BM of the gate structure 123B in FIG. 13C, and the center axis 138AX1 corresponds to the longitudinal center axis of the gate structure 123B in FIG. 13C, which longitudinal center axis of the gate structure 123B is the same as the line illustrating the cross-section A-A in FIG. 13C. FIG. 28B illustrates the width S′ of the fin shaped slices 139A and 139B, and the pitch P′ of the openings 138. Note that the width W of the openings 138 remain the same as that in FIG. 27B. As illustrated in FIG. 28B, due to the lateral shifting of the openings 138A and 138C, the width S′ of the fin shaped slices 139A and 139B is larger than the width S in FIG. 27B, and the pitch P′ of the openings 138 is larger than the pitch P in FIG. 27B. As a result, the photoresist peeling issue is avoided or reduced.

Next, referring to FIGS. 15A and 15B, the opening 138 of the photoresist layer 139 is extended through the middle layer 137 and the bottom layer 135, and is transferred to the hard mask layer 131 as an opening 132, using a suitable method, such as one or more anisotropic etching processes. For simplicity, it is assumed that after the anisotropic etching process(es), the openings 138 and 132 overlaps (e.g., are the same) in a top view. Next, the etching mask 136 is removed by a suitable process, such as etching, grinding, combinations thereof, or the like.

FIGS. 15A and 15B show the NSFET device 100 after the removal of the etching mask 136. As illustrated in FIGS. 15A and 15B, the opening 138 is transferred to the hard mask layer 131 as an opening 132 in the hard mask layer 131. The opening 132 exposes the segment 123BM (see FIG. 13C) of the gate structure 123B disposed between the dielectric plugs 125, so that the exposed segment 123BM can be removed and replaced by an isolation structure in subsequent processing, details of which are discussed hereinafter. In the top view, the shape of the opening 132 (e.g., a rectangular shape) is the same as the shape defined by the boundaries (e.g., sidewalls) of the segment 123BM of the gate structure 123B, but with a laterally offset OVS between the center axis 132X of the opening 132 and the center axis 123BX of the gate structure 123B, as indicated in FIG. 28A and shown in FIG. 15A. In some embodiments, the laterally offset OVS is controlled to be within a range such that the sidewall 132S of the opening 132 does not extend beyond a respective sidewall of the CESL 116 facing away from the gate structure 123B. In other words, the opening 132 does not expose the first ILD 114 to avoid damaging the first ILD 114 in subsequent etching processes.

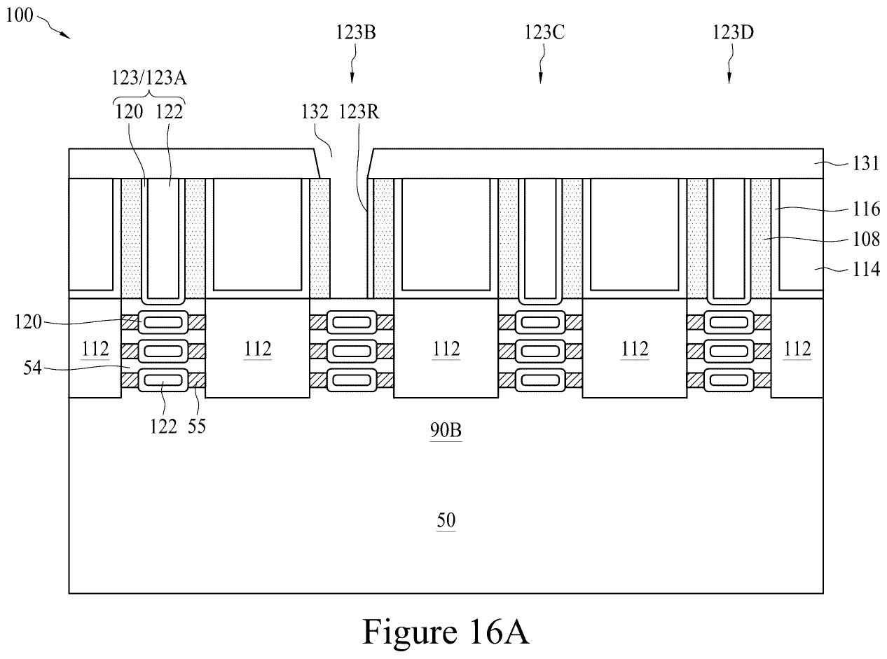

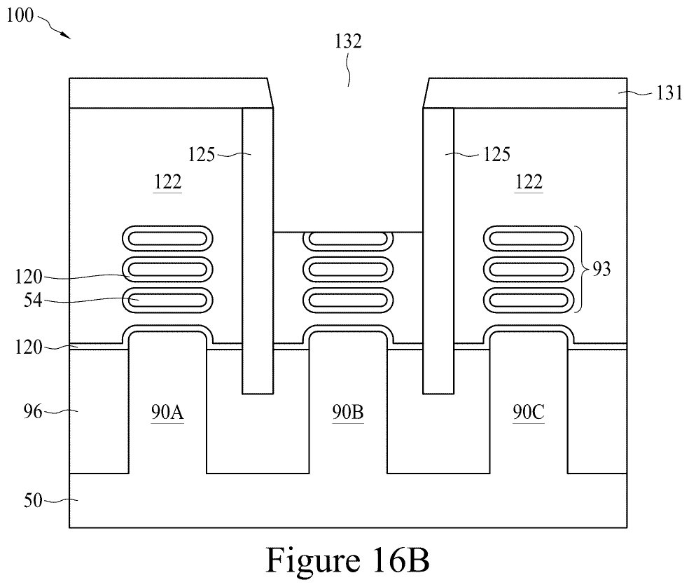

Next, in FIGS. 16A and 16B, an etching process is performed to recess the exposed segment of the gate structure 123B. In the illustrated embodiment, the etching recesses (e.g., removes) upper portions of the gate structure 123B and exposes the uppermost nanostructure 54 underlying the gate structure 123B. As a result, the opening 132 is extended into the gate structure 123B. In some embodiments, the etching process is anisotropic etching process (e.g., a plasma etching process) performed using a gas source comprising Cl₂, BCl₃, or a combination thereof. The gas source may additionally include O₂. In the illustrated example, a portion 123R of the gate structure 123B may remain along a sidewall of the gate spacer 108, due to the lateral offset OVS (see FIG. 15A) between the center axis of the opening 132 and the longitudinal center axis of the gate structure 123B, and due to the anisotropicity of the etching process. For simplicity, the portion 123R of the gate structure 123B is illustrated as a single layer, with the understanding that the portion 123R may include multiple layers of materials of the gate structure 123B, such as the gate dielectric layer 120 and one or more sublayers of the gate electrode 122, such as the barrier layer, the work function layer(s), and the gate electrode material (e.g., a fill metal). In some embodiments, a wet etching process performed using, e.g., the piranha solution (e.g., a mixture of sulfuric acid (H₂SO₄), hydrogen peroxide (H₂O₂), and water (H₂O)) is used to recess the exposed segment of the gate structure 123B.

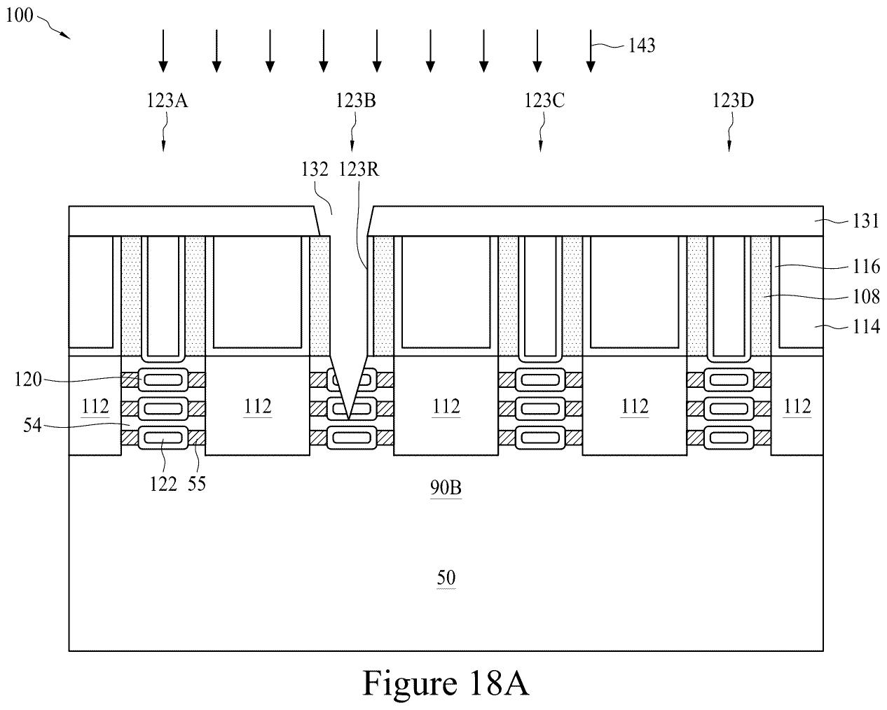

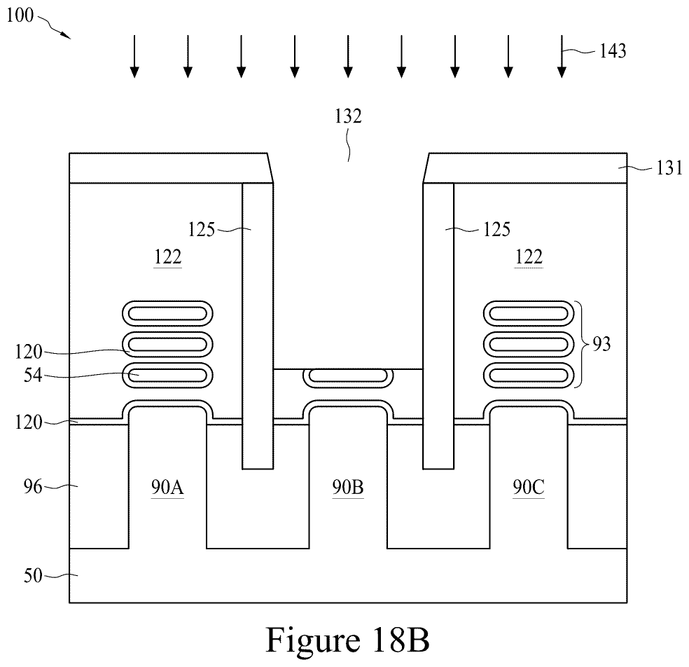

In some embodiments, the etching process discussed above for recessing the gate structure 123B may be performed using an etchant selective to the materials of the gate structure 123B, in order to selectively remove the exposed segment 123BM of the gate structure 123B without substantially attacking other layers/materials of the NSFET device 100. The hard mask layer 131, the gate spacers 108, and the dielectric plugs 125 may help to protect (e.g., shield) other areas of the NSFET device 100 from the etching process, and limit the effect of the etching process to the area defined by the opening 132. The etching process may have a high etching selectivity larger than, e.g., about 10, such as between about 10 and about 100. In the discussion herein, the etching selectivity may be calculated as a ratio between a first etch rate for target material(s) (e.g., material(s) intended to be removed by the etching process) and a second etch rate for non-target material(s) (e.g., material(s) exposed to the etching process but not intended for removal). The first etch rate or the second etch rate may be an average etch rate for the respective materials, in some embodiments. In the above discussed etching process to recess the gate structure 123B, the etching selectivity may be calculated as a ratio between the etch rate for the material(s) (e.g., Cu) of the gate structure 123B and the etch rate for the material(s) (e.g., SiO) of the gate spacers 108. In other embodiments, an etching process with low etching selectivity is used to recess the gate structure 123B. For example, the anisotropic plasma etching process 143 (see, e.g., FIG. 18A) discussed hereinafter may be used to recess the gate structure 123B.

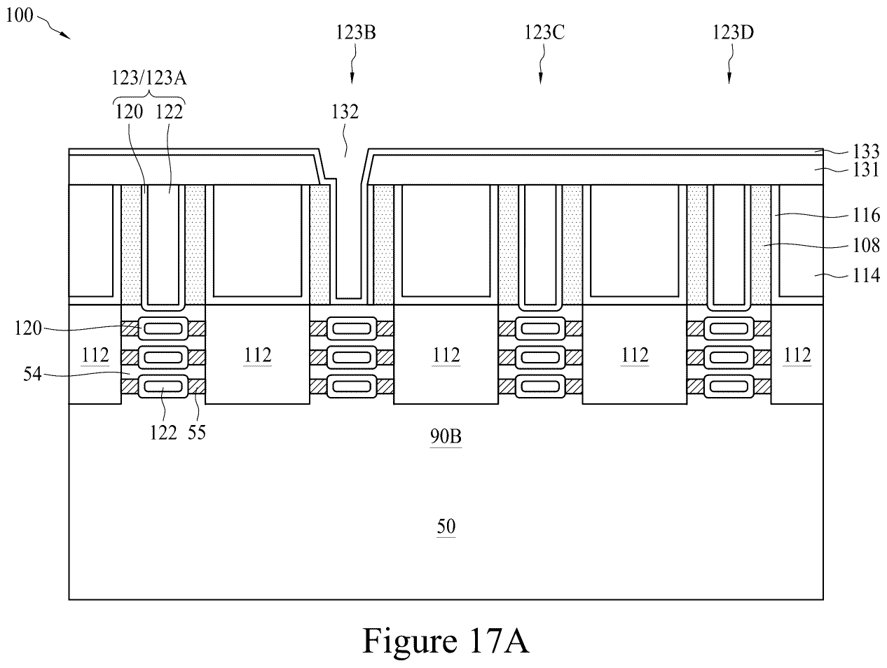

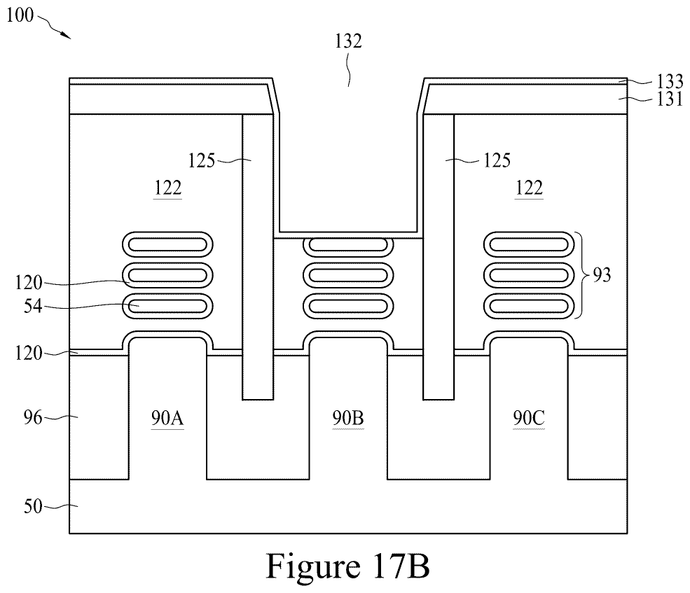

Next, in FIGS. 17A, 17B, 18A, 18B, 19A, 19B, 20A, and 20B, an etching process is performed to deepen the opening 132, in order to cut the nanostructures 54 exposed by (e.g., underlying) the opening 132 and cut lower portions of the gate structure 123B. In some embodiments, the etching process to deepen the opening 132 includes multiple etching cycles, where each etching cycle of the multiple etching cycles includes the following three sequential processing steps: 1) Deposition Step, where a passivation layer 133 is formed on the hard mask layer 131 and along the sidewalls and the bottom of the opening 132; 2) Break-Through Step, where a break-through etching step is performed to remove the passivation layer 133 from the etch front (e.g., bottom of the opening 132); and 3) Etch Step, wherein an anisotropic plasma etching process 143 with low etching selectivity is performed to remove the nanostructures 54 underlying the opening 132. Details of the etching process are discussed hereinafter.

FIGS. 17A and 17B illustrate a deposition step, where in order to protect the hard mask layer 131 and to preserve the dimension of the opening 132 during the subsequent etching steps (e.g., the break-through step and the etch step), the passivation layer 133 is formed (e.g., conformally) over the upper surface of the hard mask layer 131 and along the sidewalls and the bottom of the opening 132. The passivation layer 133 may also be formed over surfaces of the nanostructures 54. In some embodiments, the passivation layer 133 is a SiO-based passivation layer formed by injecting a silicon-containing gas (e.g., SiCl₄) and an oxygen-containing gas (e.g., O₂, CO₂) into the plasma etching tool used for deepening the opening 132 and removing the nanostructure 54. A carrier gas, such as Ar or N₂, may be used to carry, e.g., SiCl₄ and O₂ into the plasma etching tool. The SiO-based passivation layer may be formed by the chemical reaction:

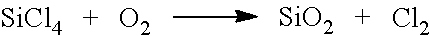

In some embodiments, addition chemical(s), such as HBr, is injected into the plasma etching tool chamber along with SiCl₄ to facilitate the dissociation of SiCl₄ in the SiO-based passivation layer formation process. Chemical reactions, such as

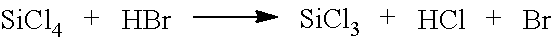 [SMILES: "SiCl4" ; Br ; "SiCl3" ; Cl ; Br]

may happen to speed up the dissociation of SiCl₄ and the formation of SiO-based passivation layer. The bromine (Br) generated by the above chemical reaction may further react with SiO₂ to form SiBrO. Therefore, the composition of the SiO-based passivation layer 133 may include SiBrO.

In some embodiments, the passivation layer 133 is a SiON layer formed by a deposition process performed using a silicon-containing precursor (e.g., Bis(t-butylamino)silane (BTBAS)) and O₂ plasma. In some embodiments, the passivation layer 133 is a SiN layer formed by a deposition process performed using a silicon-containing precursor (e.g., BTBAS) and Ar plasma.

After the passivation layer 133 is formed, a break-through step is performed to break through the passivation layer 133 at the etch front (e.g., remove the passivation layer 133 from the bottom of the opening 132), such that the etch step (e.g., anisotropic plasma etching process 143) can be performed next to remove the nanostructures 54. In some embodiments, the break-through step is an anisotropic etching process (e.g., a plasma etching process) performed using a gas source comprising CF₄, CHF₃, C₄F₆, Cl₂, BCl₃, or combinations thereof.

Next, in FIGS. 18A and 18B, an etch step is performed to deepen the opening 132 toward the substrate 50. In the illustrated embodiments, the etch step is an anisotropic plasma etching process 143, which may also be referred to as a plasma dry etching process 143. The anisotropic plasma etching process 143 may be performed using a gas source comprising HBr, Cl₂, or combinations thereof. The gas source may optionally include BCl₃. In addition, during the anisotropic plasma etching process 143, other gases, such as O₂, CO₂, or a combination thereof, may be added to the gas source to adjust various aspects of the anisotropic plasma etching process, such as etching rate, etching selectivity, and/or etching profile. The three-step etching cycle discussed above is optional. In some embodiments, the deposition step and the break-through step are omitted, and the plasma dry etching process 143 alone is used to remove the nanostructures 54 and to deepen the opening 132.

During the anisotropic plasma etching process 143, the gas source is ignited into plasma by a plasma etching tool. The plasma etching tools may use an inductively coupled dipole antenna coil to generate plasma. In some embodiments, an RF power generator of the plasma etching tool generates an RF power source (e.g., an RF signal) at 13.6 MHz. The plasma etching tool chamber may be operated at a pressure between about 3 mTorr and about 150 mTorr, and at a temperature between about 20 degrees Celsius and about 150 degrees Celsius. A power of the RF power source may be between about 0 W and about 2500 W. In some embodiments, the plasma dry etching process uses pulsed plasma etch, where a duty cycle of the RF power source is in a range between about 10% to 100%. In some embodiments, an amplitude of the bias voltage of the plasma etching tool for the anisotropic plasma etching process 143 is between about 500 Volt and about 1200 Volt to ensure a high anisotropicity (also referred to as a high directionality).

Notably, the anisotropic plasma etching process 143 has a low etching selectivity in a range between about 0.2 and about 5, such as between about 4 and about 5. A conventional CMODE process may use etching process(es) with high etching selectivity (e.g., between 10 and 100) in order to selectively remove the gate structure (e.g., 123B) first, then selectively remove the nanostructures 54. In contrast, the presently disclosure uses the anisotropic plasma etching process 143 with a low etching selectivity to cut through the nanostructures 54. The etching selectivity of the anisotropic plasma etching process 143 may be calculated as a ratio between an etch rate for the material (e.g., Si) of the nanostructures 54 (or the substrate 50) and an etch rate for the material(s) (e.g., SiO) of the gate spacer 108 (or the STI regions 96), as an example. The advantages of using the anisotropic etching process 143 with low etching selectivity are discussed hereinafter.

In some embodiments, the low etching selectivity of the anisotropic plasma etching process 143 is achieved by choosing an etchant (e.g., Cl₂) that removes both target material (e.g., Si) and the non-target material(s) (e.g., SiO). In some embodiments, the mixing ratio between the gases used in the anisotropic plasma etching process 143 is adjusted to achieve the low etching selectivity. For example, in embodiments where BCl₃ is used in the etching gas, increasing the volume percentage of BCl₃ in the etching gas may decrease the etching selectivity. In some embodiments, the etching gas may be a mixture of HBr, BCl₃, Cl₂, and O₂, where a percentage (e.g., volume percentage) of HBr in the etching gas is between 0% and 80%, a percentage of BCl₃ in the etching gas is between 5% and 80%, a percentage of Cl₂ in the etching gas is between 0% and 80%, and a percentage of O₂ in the etching gas is between 0% and 50%.

In some embodiments, the anisotropic plasma etching process 143 has a high anisotropicity (e.g., highly directional vertical etching). The high anisotropicity of the anisotropic plasma etching process 143 may be achieved by having a high bias voltage (e.g., AC bias voltage) for the anisotropic plasma etching process 143. For example, the amplitude of the bias voltage of the plasma etching tool for the anisotropic plasma etching process 143 may be high than 500 Volt (V), such as between about 500 V and about 1200 V, while the amplitude of the bias voltage used by a conventional anisotropic plasma etching process may be less than 500V, such as between about 100 V and about 500 V. Advantages of the high anisotropicity of the anisotropic plasma etching process 143 are discussed hereinafter. As illustrated in FIGS. 18A and 18B, after the etch step (e.g., anisotropic plasma etching process 143) is finished, the opening 132 is deepened and cuts into nanostructures 54. Due to the low etching selectivity of the anisotropic plasma etching process 143, the passivation layer 133 is etched away by the anisotropic plasma etching process 143, and the portion 123R of the gate structure 123B along the sidewall of the gate spacer 108 is thinned by the anisotropic plasma etching process 143. Noted that to avoid complete exhaustion of the hard mask layer 131 during the etching process, the highly anisotropic etching with high bias voltage may be applied to some steps or some cycles in the etching processing, in some embodiments. In some embodiments, the bias voltage may be pulsed (e.g., having a less than 100% duty cycle) during the anisotropic plasma etching process 143 to ensure preservation of the hard mask layer 131.

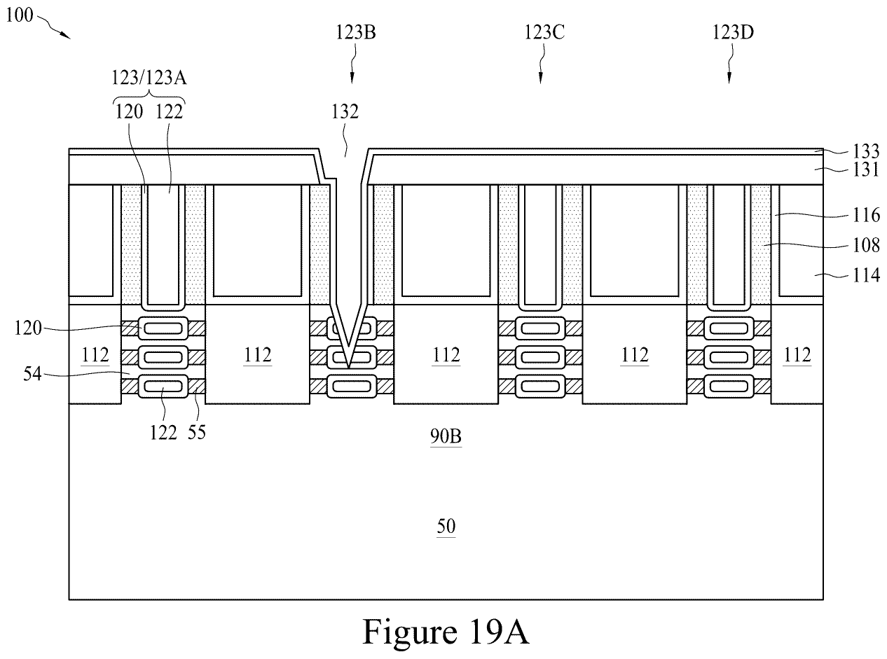

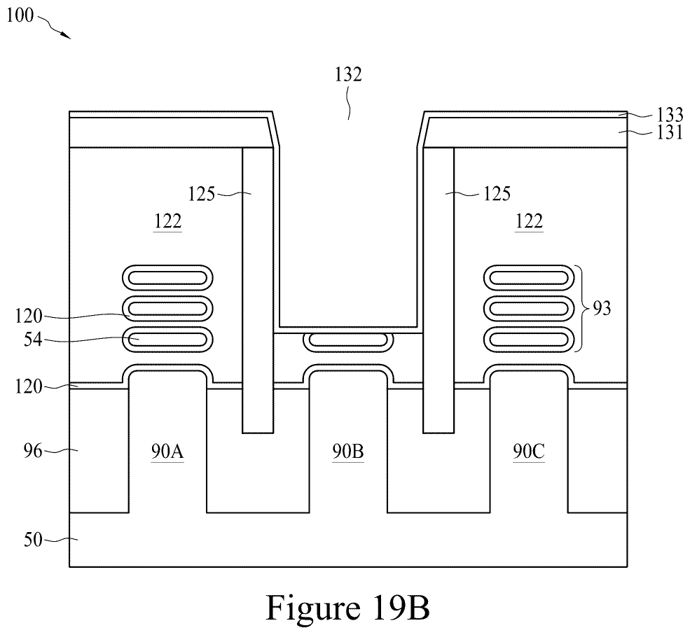

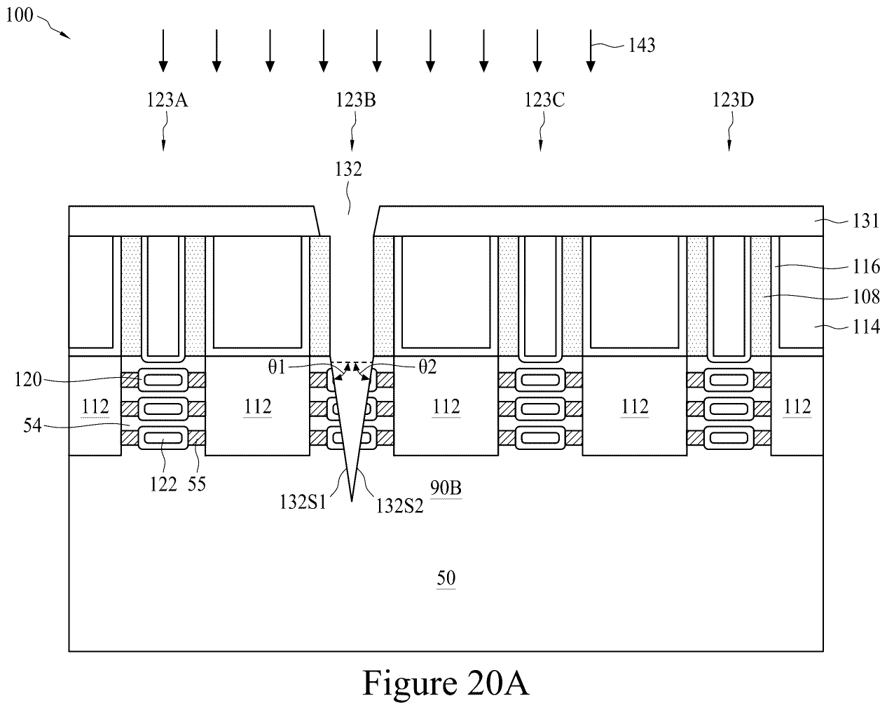

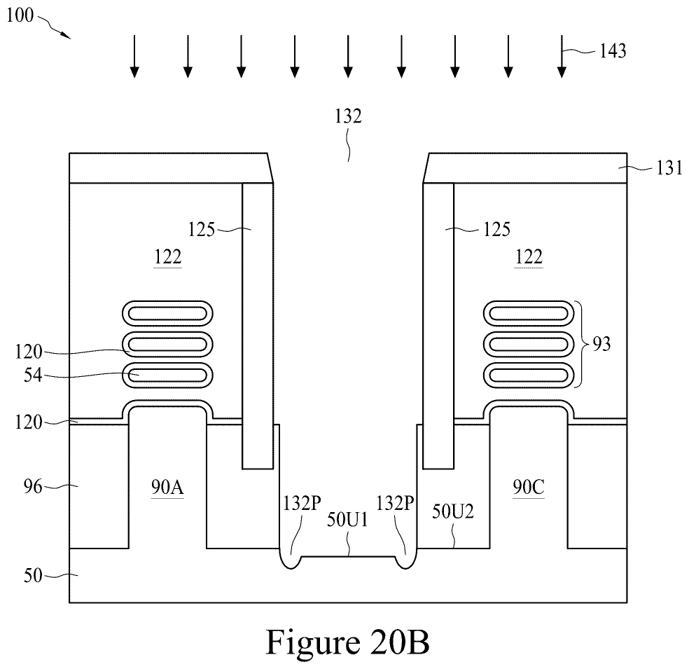

Additional etching cycles may be performed. FIGS. 19A, 19B, 20A, and 20B illustrate a subsequent etching cycle (e.g., the last etching cycle) of the etching process. In FIGS. 19A and 19B, the passivation layer 133 is formed over the mask layer 131 and along sidewalls and the bottom of the opening 132. The break-through step is performed next to remove the passivation layer 133 from the bottom of the opening 132. Next, in FIGS. 20A and 20B, the anisotropic plasma etching process 143 is performed. Details of the etching cycle are the same as or similar to those discussed above, thus not repeated.

As illustrated in FIGS. 20A and 20B, after the last etching cycle of the etching process is finished, the opening 132 extends through the nanostructures 54, through the fin 90B, and into the substrate 50. In FIG. 20A, an upper portion of the opening 132 between the gate spacers 108 has a substantially uniform width, and a lower portion of the opening 132 below the upper portion has a triangular shape, with opposing sidewalls 132S1 and 132S2 of the lower portion of the opening 132 having a liner profile and intersecting with each other to form a V-shape. An angle θ₁ between the sidewall 132S1 and the horizontal direction of FIG. 20A is between about 88 degrees and about 90 degrees, and an angle θ₂ between the sidewall 132S2 and the horizontal direction of FIG. 20A is between about 88 degrees and about 90 degrees, in some embodiments. In the example of FIG. 20A, the shape of the cross-section of the lower portion of the opening 132 (e.g., the portion disposed below the gate spacers 108) is an acute triangle (e.g., having three acute angles).

As illustrated in FIG. 20B, due to the low etching selectivity of the anisotropic plasma etching process 143, besides the nanostructures 54 and the gate structure 123B, the fin 90B and portions of the STI regions 96 under the openings 132 are also removed. Therefore, as shown in FIG. 20B, the opening 132 extends through the STI region 96 and into the substrate 50. As a result, an upper surface 50U1 (e.g., a flat upper surface) of the portions of the substrate 50 underlying the opening 132 is lower (e.g., more recessed) than an upper surface 50U2 of other (un-etched) portions of the substrate 50. Notably, in FIG. 20B, the opening 132 includes two protrusion portions 132P (also referred to as protrusions 132P, or notches 132P) at the bottom corners of the opening 132. In particular, the protrusion portions 132P extend below the upper surface 50U1 of the substrate 50 in FIG. 20B. The protrusions 132P may be formed due to faster etching rate achieved by the anisotropic plasma etching process 143 at or along the edges of the nanostructures 54.

As illustrated in FIGS. 20A and 20B, after removal of the nanostructures 54, the opening 132 (may also be referred to as a recess 132) exposes sidewalls of the dielectric plugs 125 facing the nanostructures 54, and exposes inner sidewalls of the gate spacers 108 facing the opening 132. In other words, in a top view, the opening 132 is defined by opposing sidewalls of the dielectric plugs 125 along a first direction (e.g., along the direction of cross-section A-A), and is defined by opposing sidewalls of the gate spacers 108 along a second direction (e.g., along the direction of cross-section B-B). Since the opening 132 is subsequently filled with a dielectric material to form the isolation structure 141, the location of the isolation structure 141 in the top view of FIG. 22C also illustrates the location of the opening 132 before it was filled.

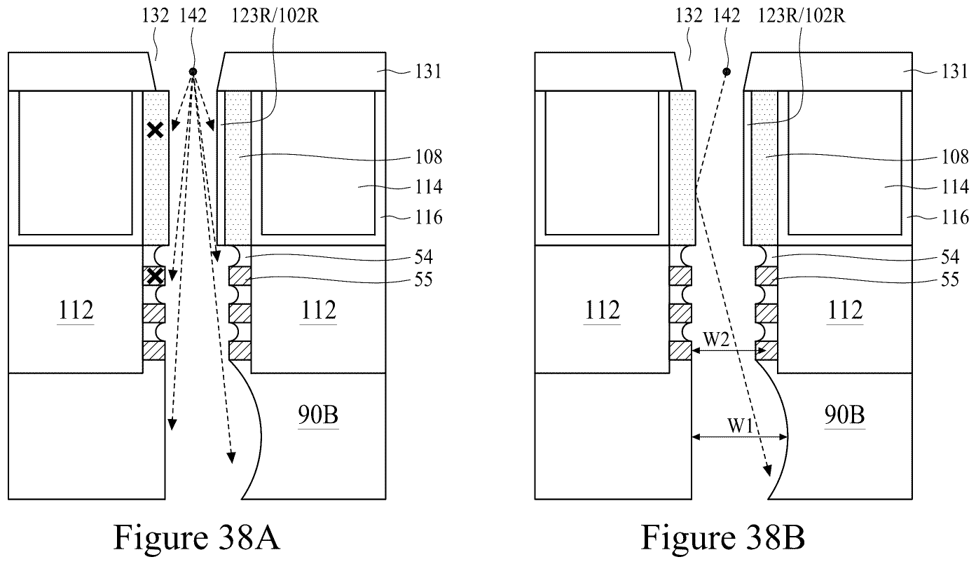

The low etching selectivity of the anisotropic plasma etching process 143 ensures that the opening 132 has a liner sidewall profile, and there is no “bowing” in the opening 132. FIG. 38B shows an example of bowing in the opening 132. Bowing occurs when the width of a section of the opening 132 is larger than the widths of adjacent sections of the opening 132. For example, if the opening 132 has a bowing condition at a certain section, that section of the opening 132 may appear as a bulge compared with other adjacent sections of the opening 132.

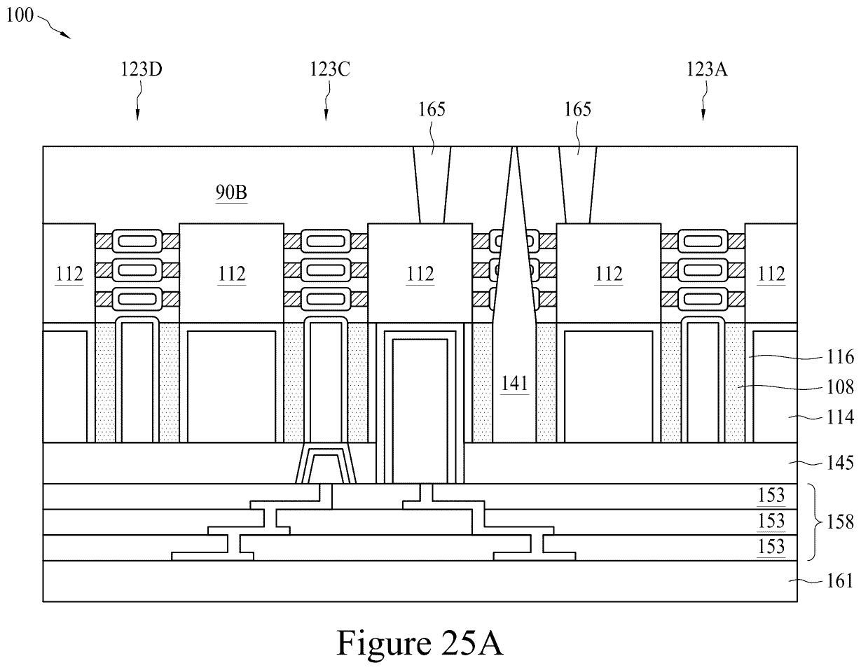

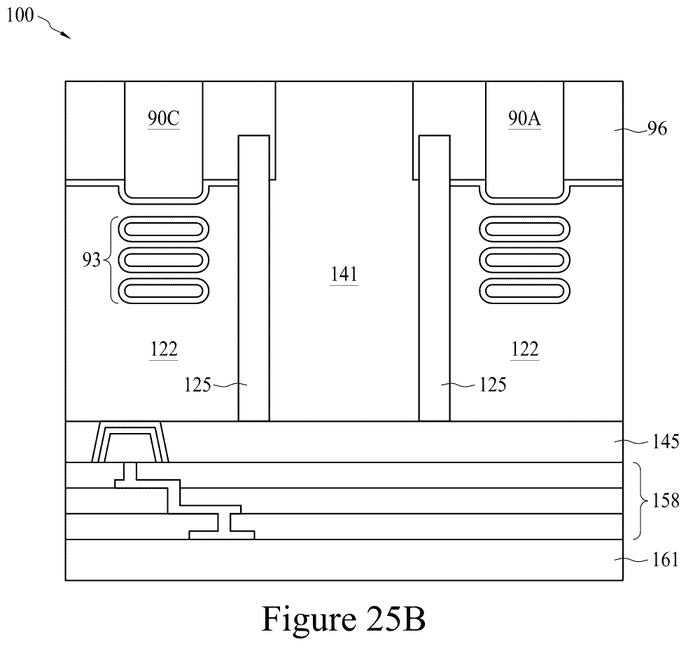

The opening 132 is subsequently filled with a dielectric material(s) to form an isolation structure 141. In subsequent processing, vias 165 (see, e.g., FIG. 25A) are formed at the backside of the substrate 50 to connect backside power rails 169 to the source/drain regions 112. If there is bowing in the opening 132, the subsequently formed isolation structure 141 may have a bulge that protrudes toward the path of the via 165 and may obstruct the formation of the via 165, thereby causing device failure. The presently disclosed methods prevent the bowing condition from happening, thus improving device reliability and production yield.

To appreciate the advantage of the presently disclosed methods, the mechanism for the bowing condition to occur and how the disclosed methods avoid the bowing condition are discussed below. Referring temporarily to FIGS. 38A and 38B, which illustrate formation of bowing in the opening 132 when an anisotropic etching process with a high etching selectivity is used to deepen the opening 132. The ions and/or radicals of the plasma used in the anisotropic etching process are labeled as ions/radicals 142 in FIGS. 38A and 38B. The dashed arrow lines in FIGS. 38A and 38B illustrate trajectories of the ions/radicals 142. Note that the sidewall of the gate spacer 108 to the right side of the opening 132 in FIGS. 38A and 38B is not exposed, and is covered by a portion 123R of the gate structure 123B (as in the embodiment method for forming the NSFET device 100), or is covered by a portion 102R of the dummy gate 102 (e.g., polysilicon) (as in the embodiment method for forming the NSFET device 100A, which is discussed hereinafter). The portions 123R or 102R are generated due to the shifting of the opening 132 to avoid photoresist peeling issue, as discussed above.

FIG. 38A illustrates etching caused by non-scattered ions/radicals 142, which refers to ions/radicals 142 which hit the surfaces of the various materials and stop in those materials. In other words, the non-scattered ions/radicals 142 do not bounce off (e.g., not reflected by) the surfaces and do not continue to travel toward the bottom of the opening 132. Due to the high etching selectivity, the non-scattered ion/radicals 142 react with certain materials (e.g., Si of the nanostructures 54) and remove them, and do not react with other materials (e.g., SiO) of, e.g., the gate spacers 108, the inner spacers 55, or the like. The “x” marks in FIG. 38A illustrate areas/regions where the non-scattered ions/radicals 142 hit but did not react with (thus with little or no removal of the material). The etching effect of the non-scattered ions/radicals 142 on the lower portion of the opening 132 (e.g., the portion below the nanostructures 54) is symmetric, thus the non-scattered ions/radicals 142 are not considered a cause for the bowing condition.

FIG. 38B illustrates etching caused by scattered ions/radicals 142, which refers to ions/radicals 142 which hit the surfaces of the various materials and bounce off the surfaces and continue to travel (e.g., toward the bottom of the opening 132). For example, the ions/radicals 142 may be highly reactive with the material (e.g., Si) of the nanostructures 54, but are not reactive with the material (e.g., SiO) of the gate spacer 108. Therefore, ions/radicals 142 may bounce off the sidewall of the gate spacer 108 disposed to the left side of the opening 132 and travel to lower portions of the opening 132, and reacts with the material (e.g., Si) of the fin 90B (or substrate 50) to remove those materials. Note that the sidewall of the gate spacer 108 to the right side of the opening 132 is not exposed, and is covered by the portion 123R of the gate structure in 123B, or is covered by a portion 102R of the dummy gate 102 (e.g., polysilicon). The ions/radicals 142 hitting the portion 123R or 102R may react with the material(s) of the portion 123R or 102R (therefore are not reflected by the portion 123R or 102R), or may be reflected less than the ions/radicals 142 hitting the sidewall of the gate spacer 108 disposed to the left side of the opening 132. Therefore, the etching effect of scattered ions/radicals 142 is not symmetric, which causes one side of the lower portion of the opening 132 to bulge out, thereby causing the bowing condition. In the example of FIG. 38B, a section of the lower portion of the opening 132 has a width W₁, which is larger than a width W₂ of an adjacent section of the opening 132. In the illustrated example, the cross-section of the opening 132 with bowing condition is not symmetric. In particular, one side (e.g., right side) of the opening 132 bulges out more than the other side, and the side with the bulging is on the same side as the gate spacer 108 whose sidewall is covered by the portion 123R or 102R.

The present disclosure, by using the anisotropic etching process 143 with low etching selectivity, ensures that there is no bowing caused by scattered ions/radicals 142. This is because due to the low etching selectivity, the ions/radicals 142 react in the same or similar way to the different materials, thereby avoiding the asymmetric etching effect of the scattered ions/radicals. For example, the ions/radicals 142 may be reactive to both the material(s) of the gate spacer 108 and to the material(s) of the portion 123R or 102R, and therefore, there is little or no scattered ions/radicals in the anisotropic etching process 143. The deepening of the opening 132 is therefore mostly caused by the non-scattered ions/radicals, which has a symmetric etching effect. Note that the linear sidewalls of the lower portion of the opening 132, which forms a V-shape (see, e.g., FIG. 20A), is characteristic of the disclosed embodiments. If scattered ions/radicals contribute significantly to the deepening of the opening 132, the lower portion of the opening 132 would have a rounded (e.g., curved) bottom and/or sidewalls.

The non-scattered ions/radicals, however, may have difficulty in reaching the deep end of the opening 132. The disclosed embodiments alleviate this issue by using a high bias voltage for the anisotropic plasma etching process 143, as discussed above. The high bias voltage increases the anisotropicity of the etching process, and allows for better directional etching (e.g., vertically downwards) to achieve deeper depth for the opening 132. In contrast, if a conventional anisotropic plasma etching process, which uses a low bias voltage (thus low anisotropicity) and high etching selectivity (thus more scattered ions/radicals), is used to deepen the opening 132, the low anisotropicity means that non-scattered ions/radicals may not be able to reach into deep end of the opening 132. However, more scattered ions/radicals compensate for the effect of the low anisotropicity, because the scattered ions/radicals can travel deeper into the opening 132 (which may cause the bowing issue). The lower portion of the opening 132 generated by the conventional anisotropic plasma etching process tend to have curved bottom surfaces due to etching by the scattered ions/radicals, which is different from the V-shaped bottom of the opening 132 generated by the disclosed methods herein.

The lower etching selectivity of the anisotropic plasma etching process 143, if used alone, may damage the hard mask layer 131 during etching and cause enlargement (e.g., widening) of the opening 132. The disclosed embodiments alleviate this issue by using the passivation layer 133 to protect the hard mask layer 131 and other exposed materials during etching. The break-through step in each etching cycle removes the passivation layer 133 from the bottom of the opening 132, so that the opening 132 can be deepened by each etching cycle.

Through the combined use of passivation layer 133, anisotropic etching process 143 with low etching selectivity, and highly directional etching (e.g., using high bias voltage), along with other disclosed features, the disclosed embodiments form the opening 132 without the bowing issue while achieving excellent control of feature dimensions and achieve target depth for the opening 132. If the passivation layer 133 and the anisotropic etching process 143 with low etching selectivity are used without the highly directional etching, the depth of the opening 132 may be limited. If the anisotropic etching process 143 with low etching selectivity and the highly directional etching are used without the passivation layer 133, there may be tremendous loss of the mask layer 131, which results in loss of control of the dimension of the features formed.

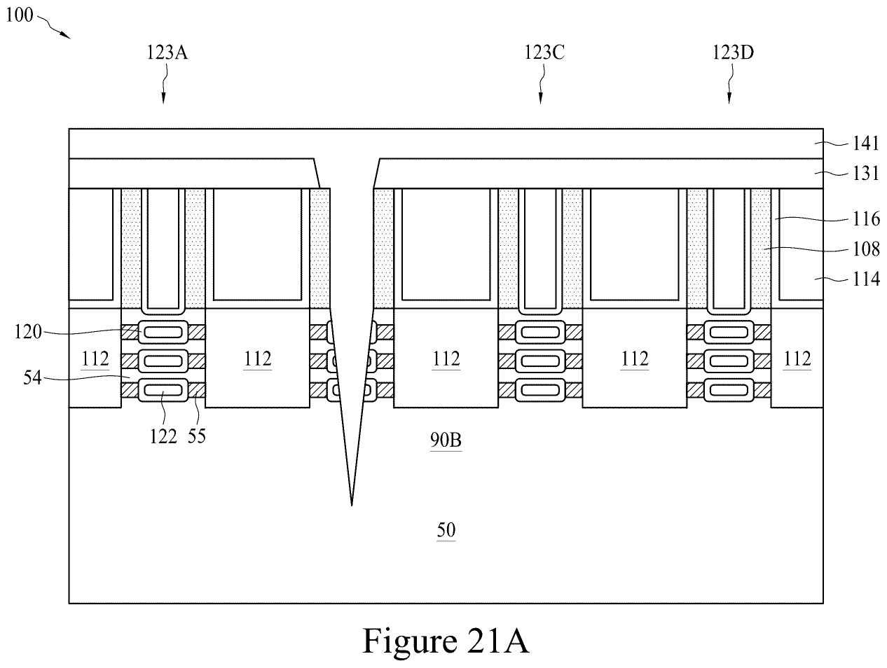

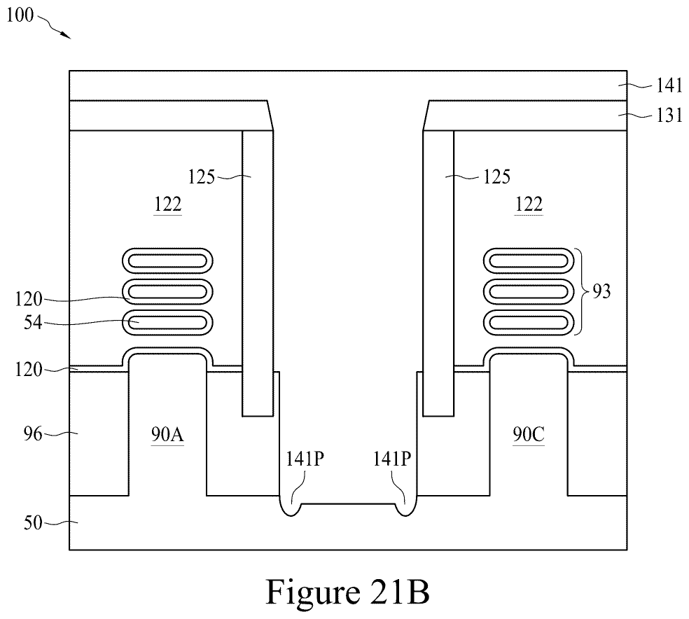

Referring now to FIGS. 21A and 21B, which illustrate the processing after the processing of FIGS. 20A and 20B. As illustrated in FIGS. 21A and 21B, a dielectric material 141 is formed in the opening 132 and over the hard mask layer 131. The dielectric material 141 may be, e.g., silicon oxide, silicon nitride, silicon oxynitride, silicon oxycarbonitride, combinations thereof, or multilayers thereof. A suitable formation method, such as CVD, PECVD, ALD, or the like, may be used to form the dielectric material 141. The dielectric material 141 may fill the notches 132P to form protrusions 141P. In some embodiments, the dielectric material 141 includes multiple layers of different dielectric materials. In some embodiments, the dielectric material 141 includes multiple layers of the same dielectric material (e.g., SiO, or SiN) formed by different formation methods. For example, a layer of the dielectric material may be formed by ALD, then another layer of the same dielectric material may be formed by, e.g., CVD, to fill the opening 132. The dielectric material formed by ALD may be dense and have improved etching resistance, while the dielectric material formed by CVD can be formed quickly to reduce production time and cost.

Next, in FIGS. 22A and 22B, a planarization process, such as CMP, is performed to remove the dielectric material 141 and the hard mask layer 131 from the upper surface of the first ILD 114. The remaining portions of the dielectric material 141 in the opening 132 form an isolation structure 141. FIG. 22C shows the top view (e.g., a plan view) of the NSFET device 100. Similar to FIG. 13C, for simplicity, not all features of the NSFET device 100 are illustrated in FIG. 22C. In the illustrated example of FIG. 22C, the isolation structure 141 is disposed between the dielectric plugs 125 along the direction of cross-section A-A, and is disposed between the gate spacers 108 of the gate structure 123B along the direction of cross-section B-B. In the illustrated embodiment of FIGS. 22A and 22B, the isolation structure 141 and the dielectric plugs 125 separate the gate structure 123B into two separate gate structures 123B1 and 123B2. The isolation structure 141 also reduces leakage current through the source/drain regions 112, the transistors, and the substrate 50. FIGS. 22A and 22B further illustrate the etch stop layer 51 embedded in the substrate 50.

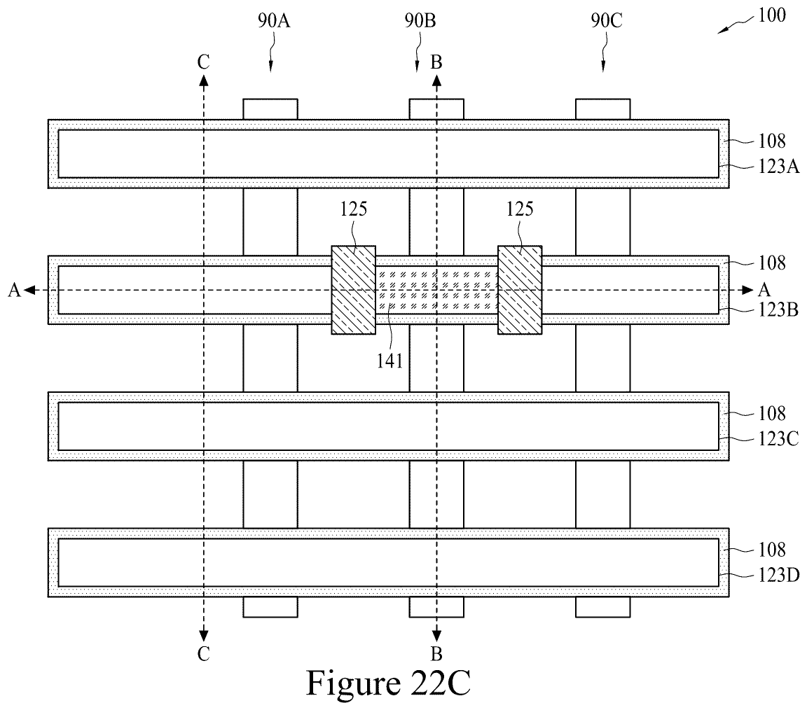

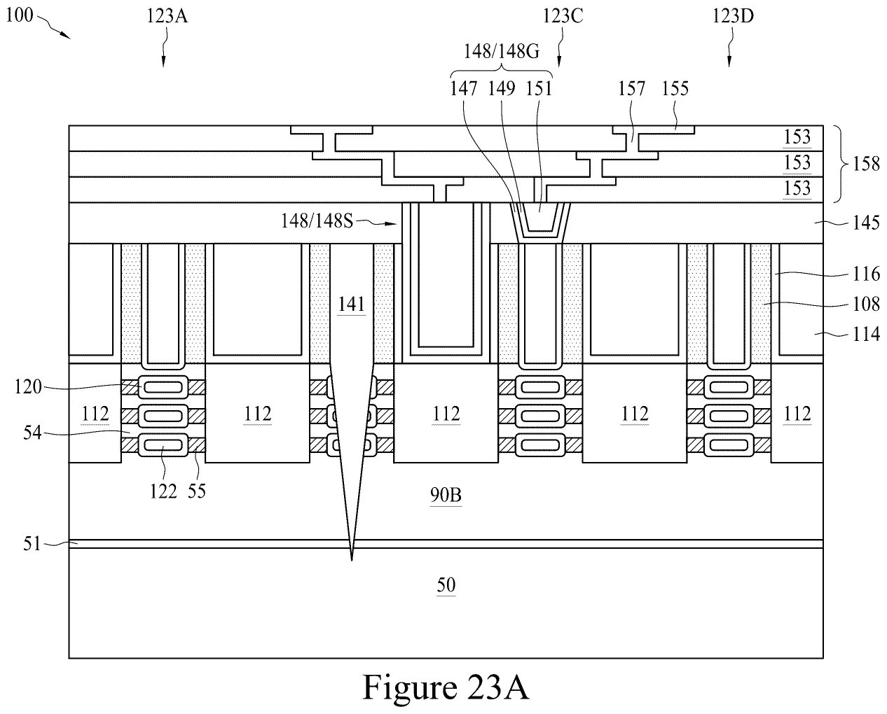

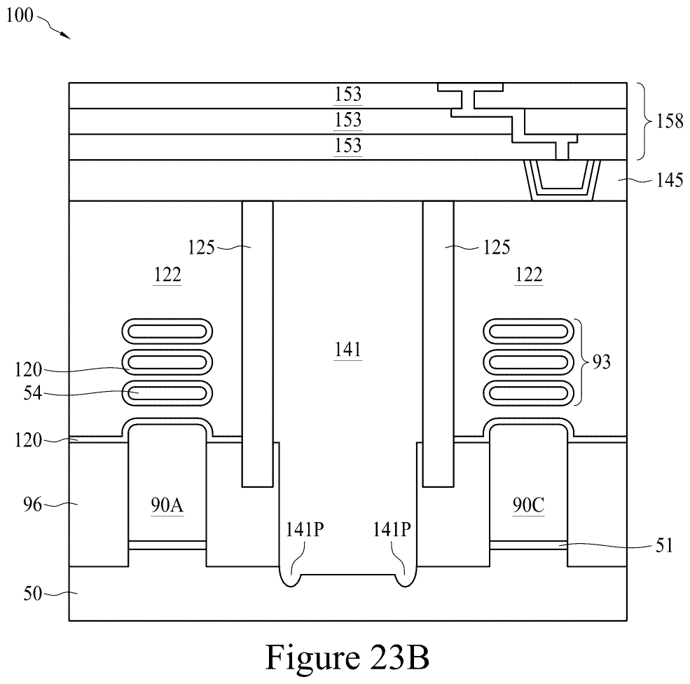

Next, in FIGS. 23A and 23B, a second ILD 145 is formed over the first ILD 114. Source/drain contacts 148S are formed to extend through the first ILD 114 and the second ILD 145 to electrically coupled to respective source/drain regions 112. Gate contacts 148G are formed to extend through the second ILD 145 to electrically coupled to respective gate structures 123. The source/drain contacts 148S and the gate contacts 148G are collectively referred to as contacts 148. In addition, an interconnect structure 158 (also referred to as front-side interconnect structure 158), which includes dielectric layers 153 and conducive features (e.g., conductive lines 155 and vias 157) formed in the dielectric layers 153, is formed over the second ILD 145 to interconnect the electrical components formed in/on the substrate 50 to form functional circuits.

The second ILD 145 may be formed of a same dielectric material as the first ILD 114 using a same formation method. Each of the contacts 148 may include a barrier layer 147 (e.g., TiN, TaN or the like), a seed layer 149 (e.g., Cu), and a fill metal 151 (e.g., Cu, W, Co, or the like). In some embodiments, the source/drain contact 148S is formed by: forming a patterned mask layer over the second ILD 145, where an opening of the patterned mask layer overlies a respective source/drain region 112; removing a portion of the second ILD 145 and a portion of the first ILD 114 that underlie the opening; conformally forming the barrier layer 147 and the seed layer 149 in the openings; and filling the opening with the fill metal 151. The patterned mask layer is then removed, e.g., by a CMP process. Note that in the example of FIG. 23A, the portion of the first ILD 114 disposed between respective sidewalls of the CESL 116 is completely removed, such that the barrier layer 147 of the source/drain contact 148S contacts (e.g., physically contacts) the sidewalls of the CESL 116. The illustrated source/drain contact 148S achieves increased volume and reduced electrical resistance, which improves the electrical performance of the device formed. The dielectric layers 153 of the interconnect structure 158 may be formed of a suitable dielectric material, such as SiO or a low-k dielectric material. The conductive lines 155 and the vias 157 of the interconnect structure 158 may be formed of a suitable electrically conductive material(s) (e.g., Cu).

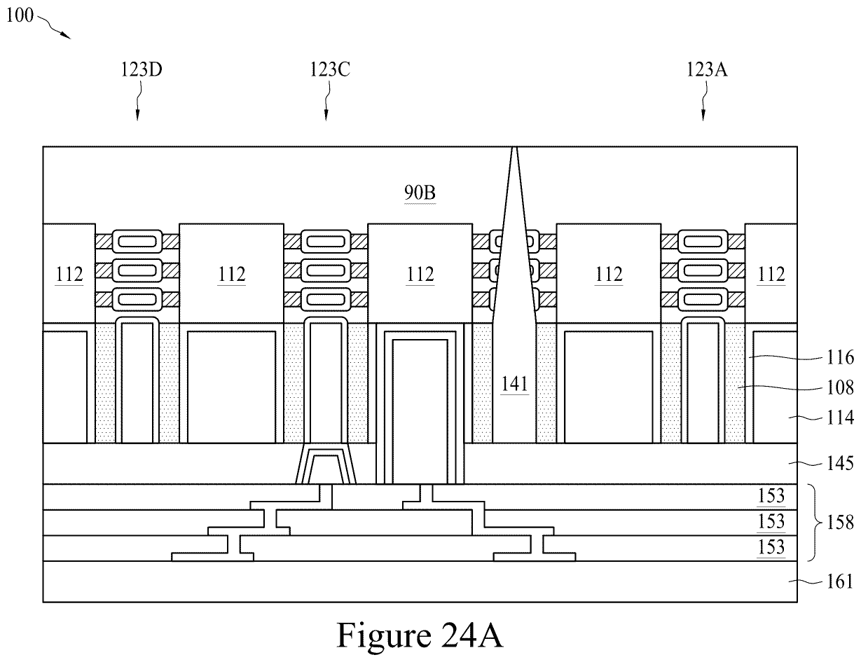

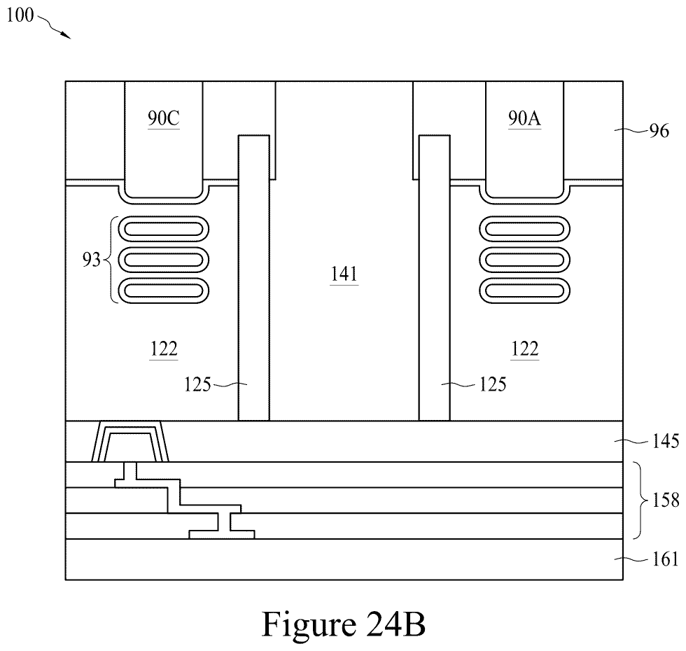

Next, in FIGS. 24A and 24B, the interconnect structure 158 is attached to a carrier 161 (e.g., a glass carrier, a ceramic carrier, a wafer, or the like) by, e.g., an adhesive layer. Next, a backside thinning process, such as CMP, a grinding process, or the like, is performed to thin the NSFET device 100 from the backside of the substrate 50. The backside thinning process may use the etch stop layer 51 to determine when to stop. In the illustrated example, after the backside thinning process is finished, the substrate 50, the etch stop layer 51, and portions of the fins 90 are removed. The isolations structure 141, the fins 90, and the STI regions 96 have a coplanar upper surface in FIGS. 24A and 24B.

Next, in FIGS. 25A and 25B, vias 165 (also referred to as backside vias 165) are formed to extend through the fin 90B to connect with the source/drain regions 112. The vias 165 may be formed by patterning the fin 90B to form openings, lining the sidewalls of the openings with a barrier layer (e.g., TiN, TaN, or the like), then fill the openings with an electrically conductive material (e.g. Cu, W, Co, or the like). In some embodiments, the backside vias 165 are formed to connect with respective source regions 112 but not drain regions 112, or to connect with respective drain regions 112 but not source regions 112. In some embodiments, the backside vias 165 are formed to connect with both source regions 112 and drain regions 112.

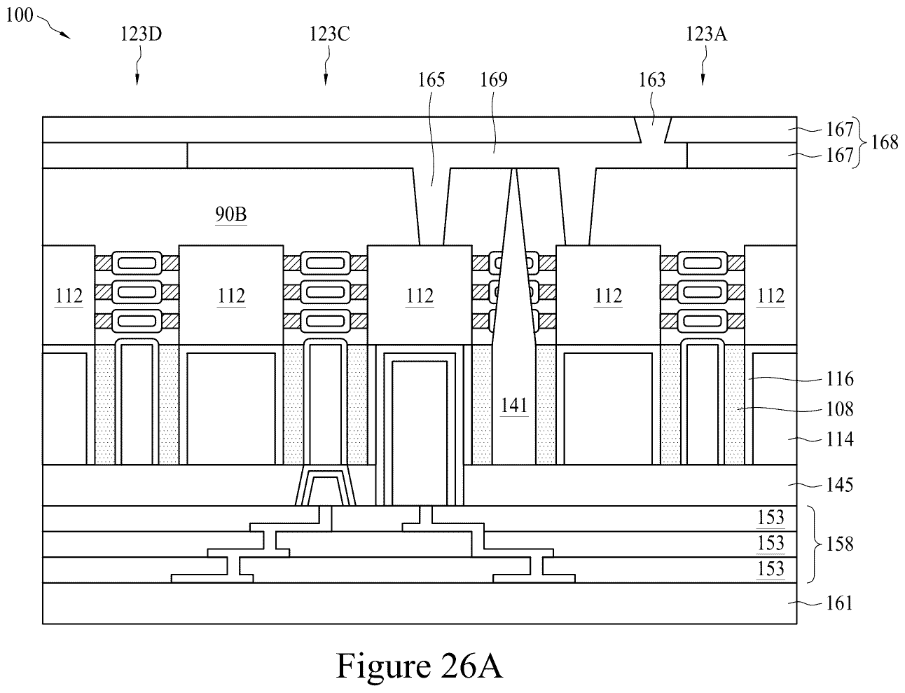

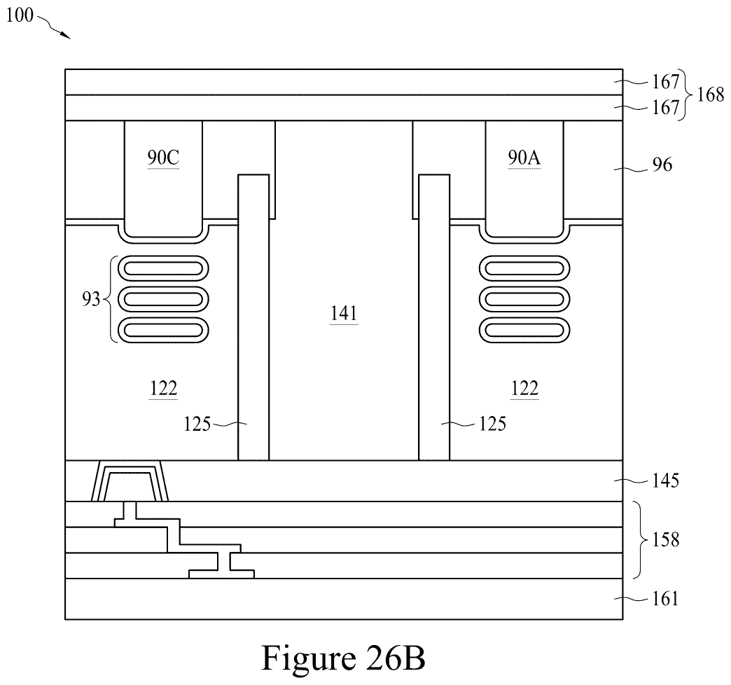

Next, in FIGS. 26A and 26B, a backside interconnect structure 168 is formed over the fin 90B and electrically coupled to the vias 165. The backside interconnect structure 168 includes dielectric layers 167 and conducive features, such as conductive lines 169 and vias 163 formed in the dielectric layers 167. The number of dielectric layers and the conductive features of the front-side interconnect structure 158 and the backside interconnect structure 168 illustrated in FIGS. 26A and 26B are illustrative and non-limiting, as skilled artisans readily appreciate.

In some embodiments, the conductive line 169 of the backside interconnect structure 168 is configured to provide a reference voltage, a supply voltage (e.g., +3V, +5V, or the like), or the like, to the source/drain regions 112, and may be referred to as a power rail 169. By placing power rails on a backside of the resulting semiconductor die rather than on a front-side of the semiconductor die, advantages may be achieved. For example, the gate density of the NSFET device and/or interconnect density of the front-side interconnect structure 158 may be increased. In addition, the backside of the semiconductor die may accommodate wider power rails, reducing resistance and increasing efficiency of power delivery to the NSFET device. For example, a width of the conductive lines 169 may be at least twice that of the conductive lines of the front-side interconnect structure 158. Furthermore, capacitors, such as metal-insulator-metal (MIM) capacitors, may be integrated in the backside interconnect structure 168 to form power circuits and/or to stabilize reference voltages and/or supply voltages in the backside power distribution network, thus achieving improved performance for the device formed.

Additional processing may be performed to complete the fabrication of the NSFET device, as skilled artisans readily appreciate. For example, external connectors (e.g., copper pillars, conductive bumps) may be formed to be electrically coupled to the front-side interconnect structure 158 and/or the backside interconnect structure 168. Dicing may be performed to separate multiple NSFET devices into separate devices. Details are not discussed here.

The cutting of the gate structure and the nanostructures of the NSFET device 100 is performed after the dummy gate structures are replaced by the replacement gate structures, and is referred to as a Continuous Metal On Diffusion Edge (CMODE) process (also referred to as a Cut Metal on-Diffusion Edge (CMODE) process). A Continuous Poly On Diffusion Edge (CPODE) process (also referred to as a Cut Poly On Diffusion Edge (CPODE) process), where the cutting of the gate structure and the nanostructures are performed on the dummy gate structure before the replacement gate structures are formed, are discussed hereinafter for a NSFET device 100A.

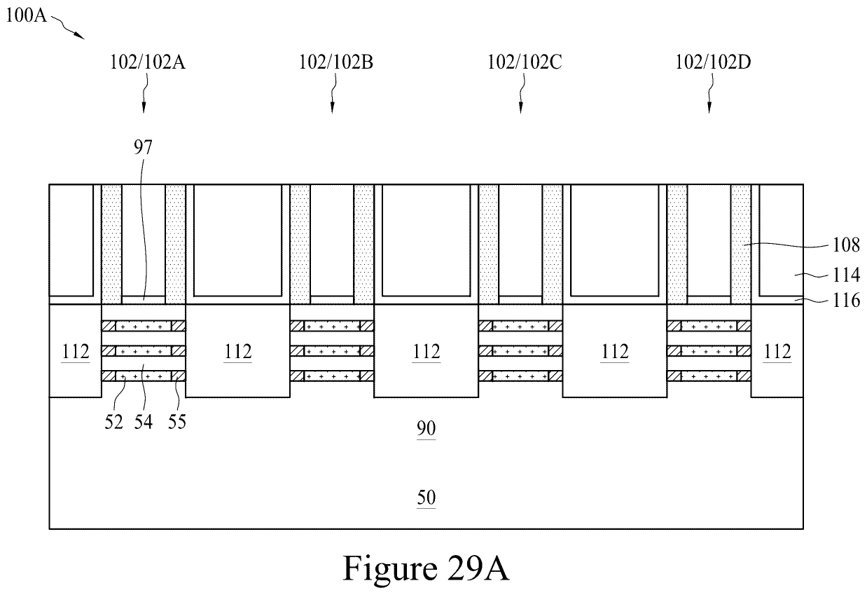

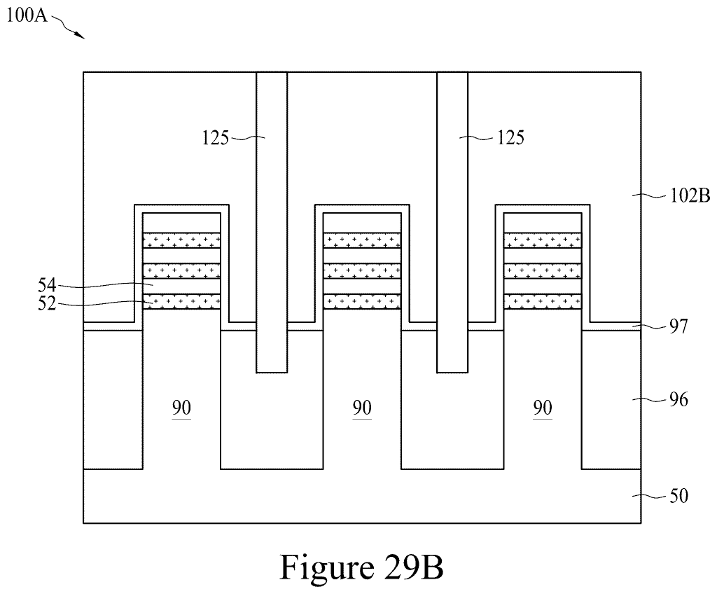

FIGS. 29A, 29B, 30A, 30B, 31A, 31B, 32A, 32B, 33A, 33B, 34A, 34B, 35A, 35B, 36A-36C, 37A, and 37B are various views of a nanostructure field-effect transistor (NSFET) device 100A at various stages of manufacturing, in accordance with another embodiment. The formation process of the NSFET device 100A has many similarities with that of the NSFET device 100. For simplicity, the discussion hereinafter focuses on the differences, and details regarding the composition and formation method of some materials (or features) that have been discussed above in the context of NSFET device 100 may not be repeated.

The processing of FIGS. 29A and 29B follows the processing of FIGS. 7A-7C, where the CESL 116 and the first ILD 114 are formed. In FIGS. 29A and 29B, a planarization process, such as CMP, is performed to level the top surfaces of the first ILD 114 and CESL 116 with the top surfaces of the dummy gates 102 and gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102A, 102B, 102C, and 102D (collectively referred to as dummy gates 102) are exposed through the first ILD 114.

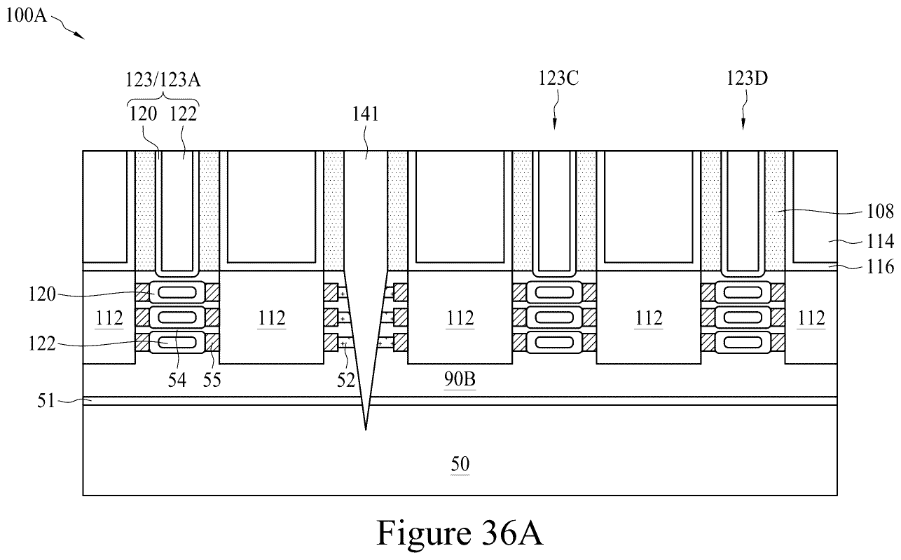

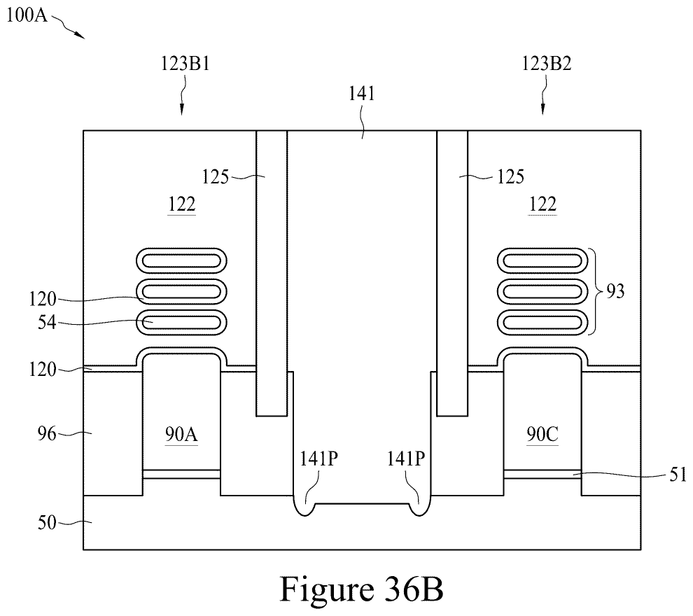

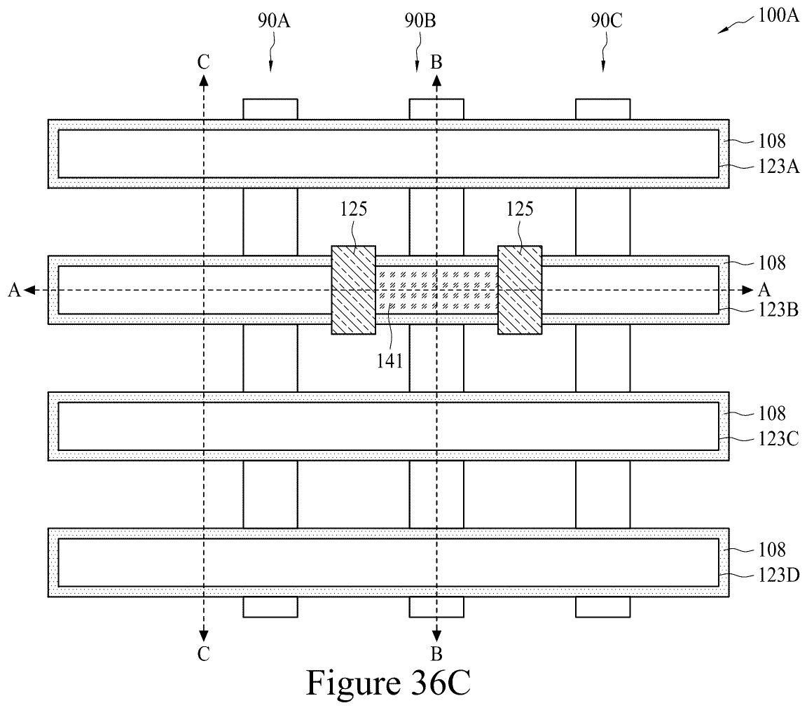

Next, the dielectric plugs 125 are formed in the dummy gate 102B, using the same or similar formation methods as discussed above for the dielectric plugs 125 in FIG. 13B. A top view of the dielectric plug 125 is shown in FIG. 36C. The dielectric plugs 125 in FIG. 29B separate the dummy gate 102B into a plurality of separate segments.

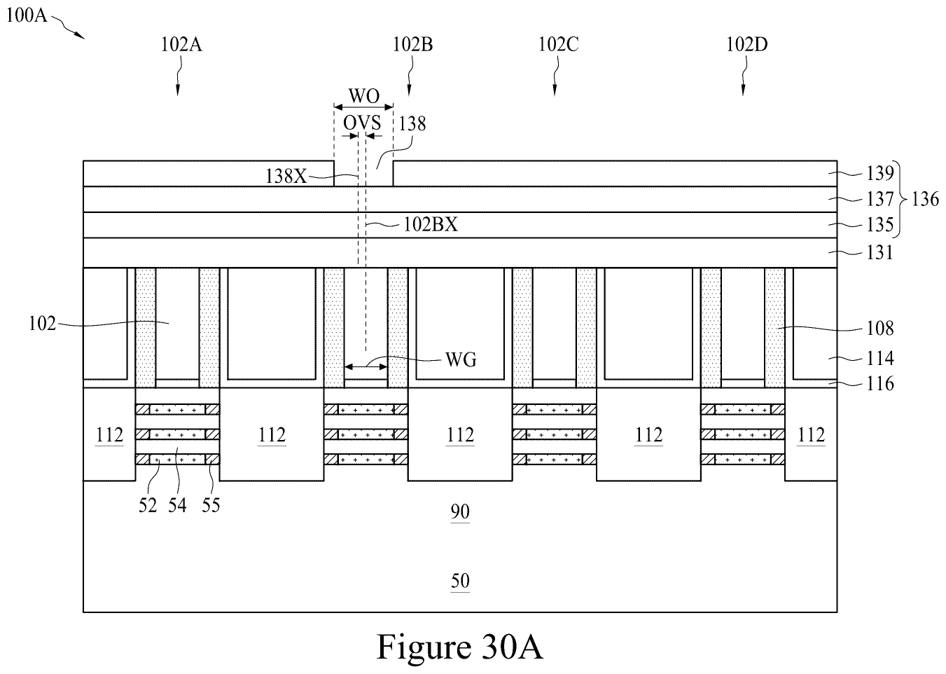

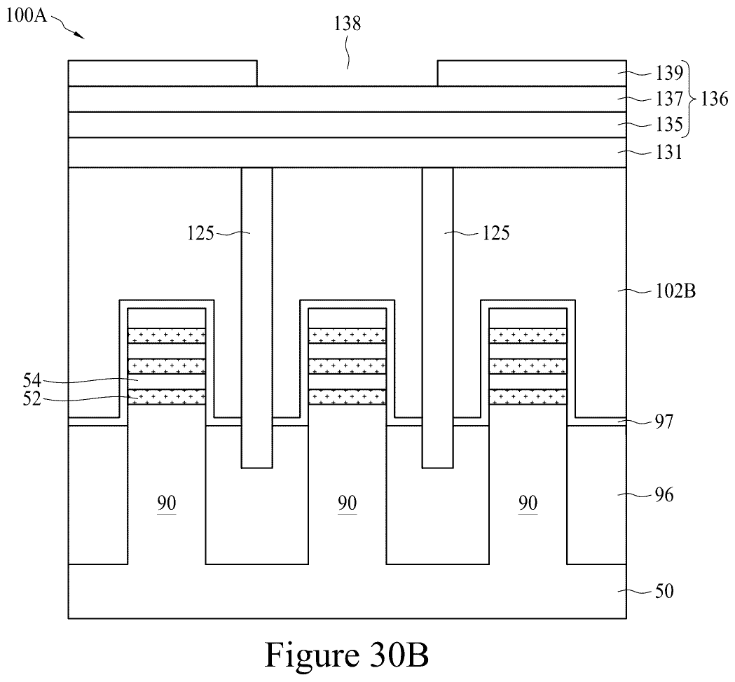

Next, in FIGS. 30A and 30B, the hard mask layer 131 is formed over the first ILD 114. The tri-layered etching mask 136 is formed over the hard mask layer 131. An opening 138 is formed in the top photoresist layer 139 of the etching mask 136. Similar to FIG. 14A, the opening 138 in FIG. 30A is purposely formed to have a lateral offset OVS between a center axis 138X of the opening 138 and a center axis 102BX of the dummy gate 102B. The amount of lateral offset OVS is the same as or similar to those discussed above for the NSFET device 100, in some embodiments, thus details are not repeated.

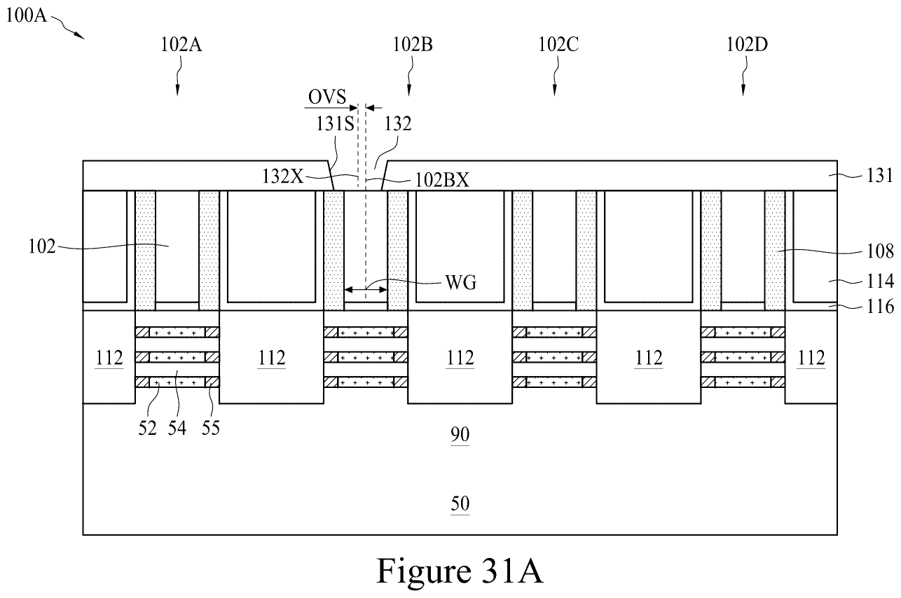

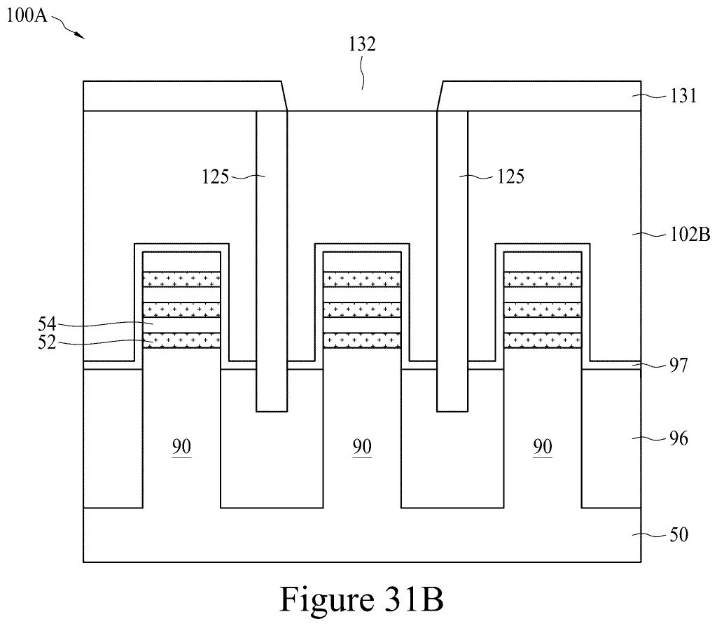

Next, in FIGS. 31A and 31B, the opening 138 in the etching mask 136 is transferred to the hard mask layer 131 as the opening 132 in the mask layer 131. There is a lateral offset OVS between the center axis 132X of the opening 132 and the center axis 102BX of the dummy gate 102B.

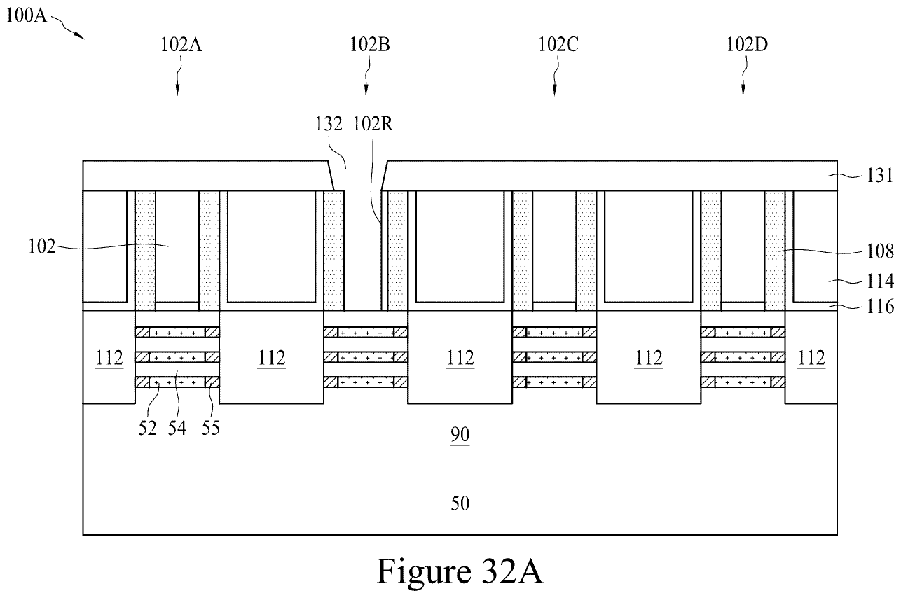

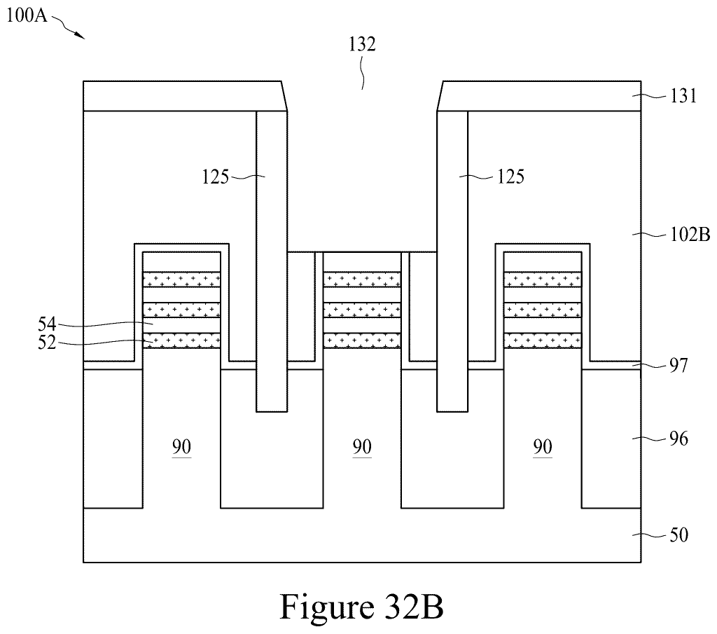

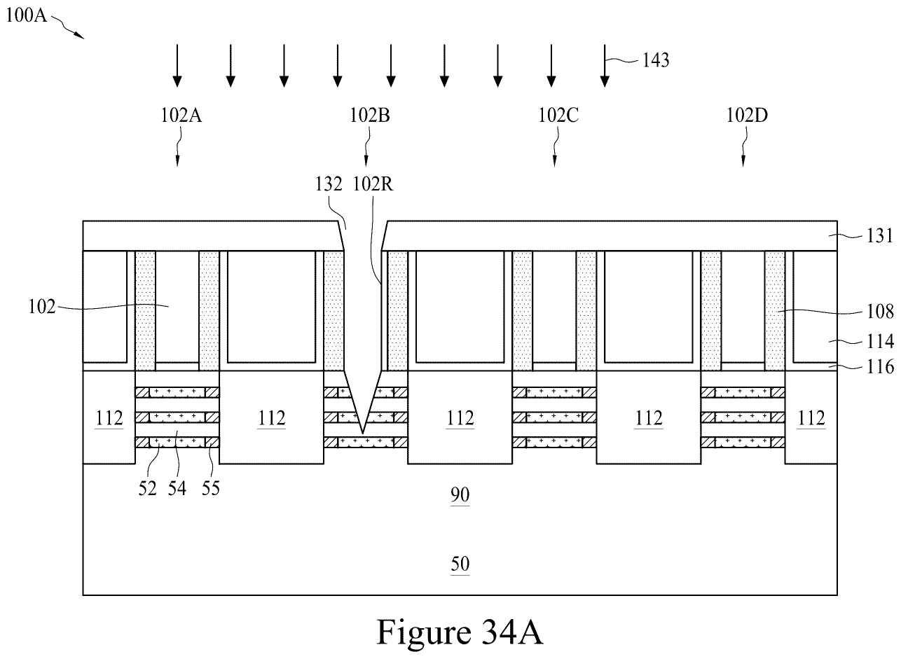

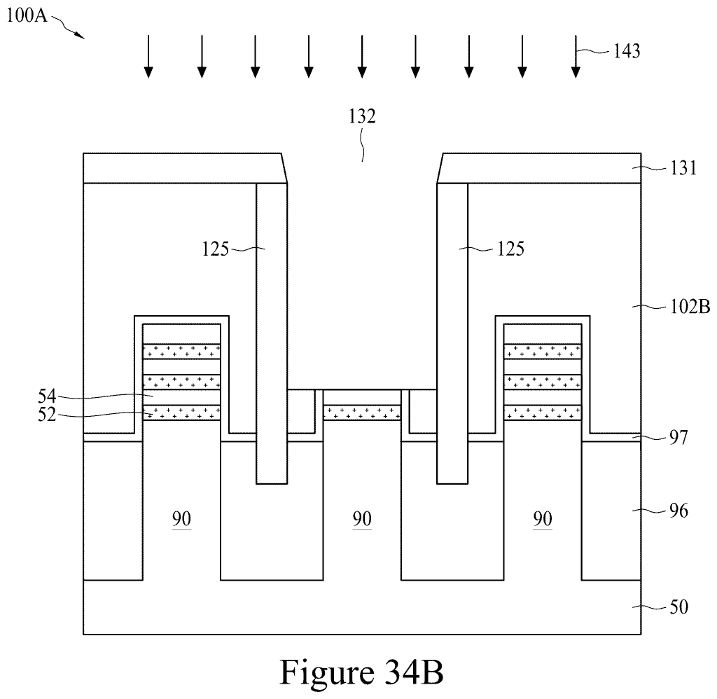

Next, in FIGS. 32A and 32B, a portion of the dummy gate 102B exposed by (e.g., underlying) the opening 132 is recessed by a suitable etching process, such as an anisotropic etching process. The anisotropic etching process may be a plasma etching use an etchant selective to the material of the dummy gate 102B, in some embodiments. The plasma etching process may use a gas source comprising a mixture of NF₃ and CH₄, or a mixture of NF₃ and CH₃F, as an example. The plasma etching process may use a gas source comprising a mixture of HBr and O₂, or a mixture of HBr and CO₂, as another example. The plasma etching process may use a gas source comprising a mixture of Cl₂ and O₂, as yet another example. In some embodiments, the anisotropic etching process may be the same etching process (e.g., 143 in FIG. 34A) used for deepening the opening 132. In the illustrated embodiment, after the processing of FIGS. 32A and 32B, the topmost nanostructure 54 underlying the opening 132 is exposed by the opening 132. A portion 102R of the dummy gate 102B (e.g., polysilicon) may remain along a sidewall of the gate spacer 108, due to the lateral offset OVS.

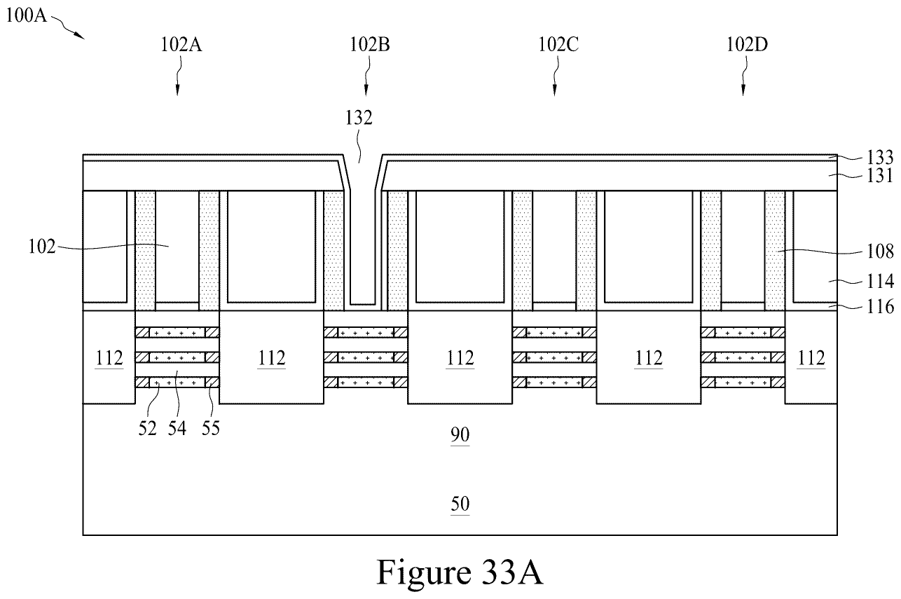

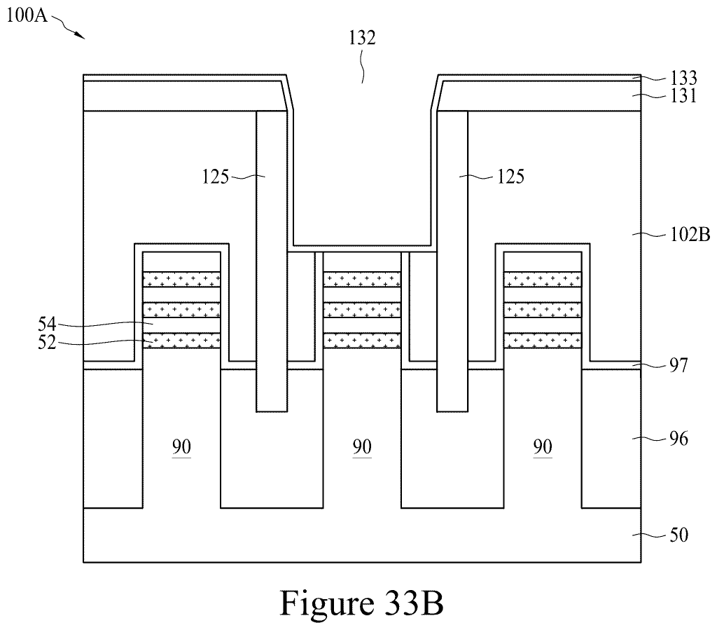

Next, as illustrated in FIGS. 33A, 33B, 34A, and 34B, a plurality of etching cycles are performed to deepen the opening 132. Each of the etching cycles includes the following three sequential processing steps: 1) Deposition Step, where the passivation layer 133 is formed on the hard mask layer 131 and along the sidewalls and the bottom of the opening 132; 2) Break-Through Step, where the break-through etching step is performed to remove the passivation layer 133 from the etch front (e.g., bottom of the opening 132); and 3) Etch Step, wherein the anisotropic plasma etching process 143 with low etching selectivity is performed to remove the nanostructures 54 underlying the opening 132. Details of the etching cycle are the same as or similar to those discussed above, thus not repeated here. The three-step etching cycle discussed above is optional. In some embodiments, the deposition step and the break-through step are omitted, and the plasma dry etching process 143 alone is used to remove the nanostructures 54 and to deepen the opening 132.

FIGS. 33A, 33B, 34A, and 34B illustrate one of the etching cycles. In FIGS. 33A and 33B, the passivation layer 133 is formed over the mask layer 131, and to line the sidewalls and the bottom of the opening 132. Next, the break-through step is performed to remove the passivation layer 133 from the bottom of the opening 132.

Next, in FIGS. 34A and 34B, the anisotropic plasma etching process 143 with low etching selectivity is performed to deepen the opening 132. Multiple etching cycles, as illustrated in FIGS. 33A, 33B, 34A, and 34B and discussed above, may be performed.

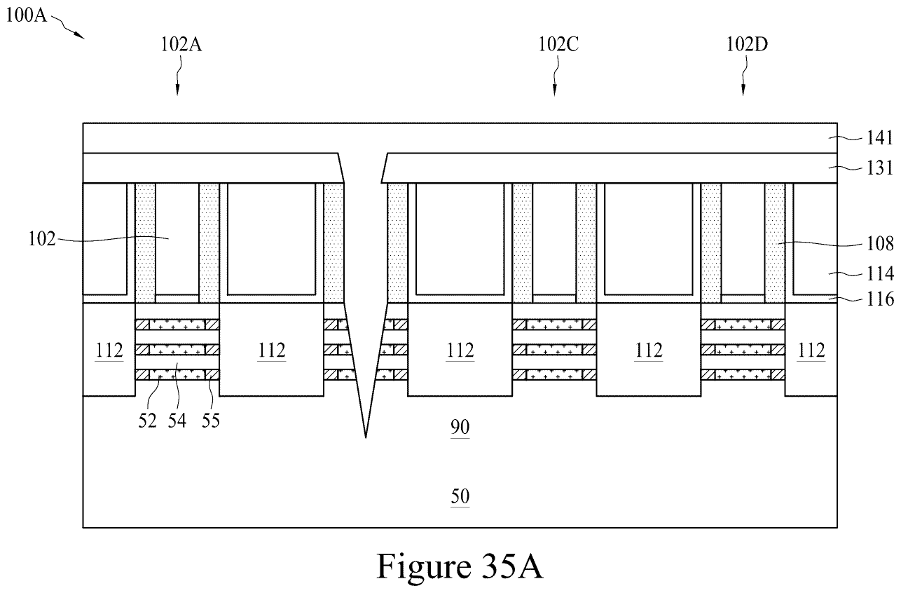

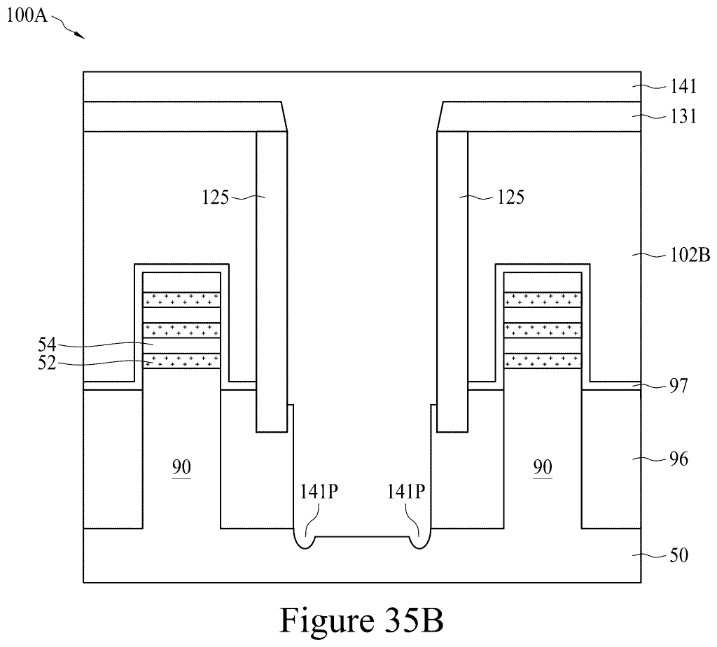

Next, in FIGS. 35A and 35B, after the plurality of etching cycles are finished, the opening 132 is filled with a dielectric material 141. The dielectric material may also be formed over the upper surfaces of the mask layer 131.

Next, in FIGS. 36A and 36B, a planarization process, such as CMP, is performed to remove the dielectric material 141 and the hard mask layer 131 from the upper surface of the first ILD 114. The remaining portions of the dielectric material 141 in the opening 132 form an isolation structure 141. Next, the dummy gates 102 and the dummy gate dielectric 97 are replaced by replacement gate structures 123 (e.g., 123A, 123B, 123C, and 123D), using the same or similar replacement gate process as discussed above. Note that the two segments of the dummy gates 102B disposed on opposing sides of the isolation structure 141 are replaced into two separate replacement gate structures 123B1 and 123B2. The gate structures 123B1 and 123B2 may be collectively referred to as gate structures 123B. FIG. 36C shows the top view (e.g., a plan view) of the NSFET device 100A.

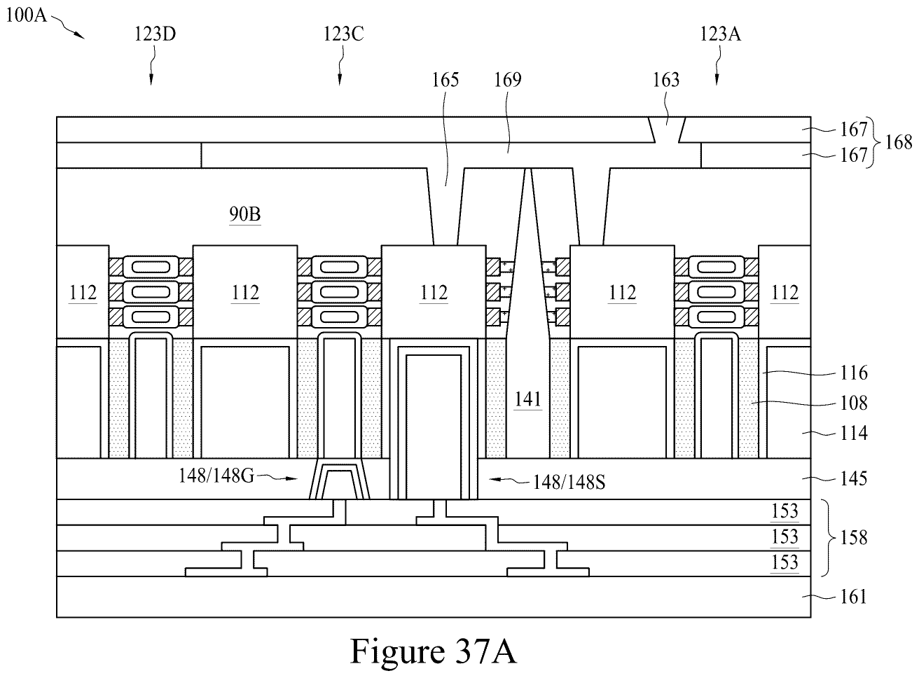

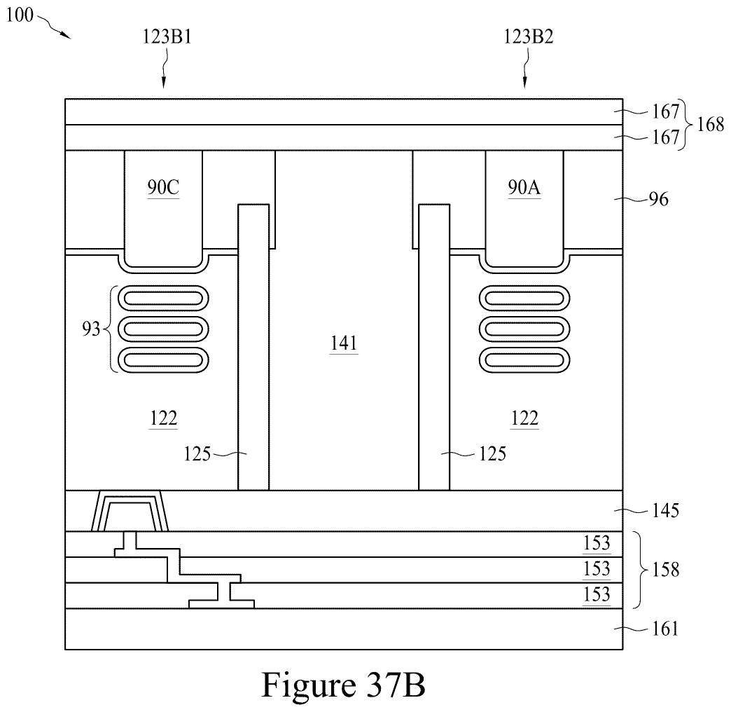

Next, in FIGS. 37A and 37B, the second ILD 145 is formed on the first ILD 114. Source/drain contacts 148S and gate contacts 148G are formed to electrically couple to respective source/drain regions 112 and gate structures 123. The front-side interconnect structure 158 is formed over the second ILD 145. Next, the front-side interconnect structure 158 is attached to the carrier 161, and a backside thinning process is performed to remove the substrate 50 and portions of the fins 90. Next, the vias 165 are formed that extend through the fin 90B to electrically couple to the source/drain regions 112. Next, the backside interconnect structure 168 is formed on the fin 90B. Power rails 169 are formed in the backside interconnect structure 168. Details are the same as or similar to those discussed above, thus not repeated here. Additional processing may be performed to finish the fabrication of the NSFET device 100A, as skilled artisans readily appreciate, details are no discussed here.

Embodiments may achieve advantages. By purposely shifting the location of the opening 138 in the photoresist layer 139, photoresist peeling issue is avoided. However, shifting the location of the opening 138 may cause bowing issue for the opening 132 during the CMODE or CPODE process. The present disclosure avoids the bowing issue by using an etching process with low etching selectivity. The etching process may optionally include a plurality of etching cycles, with each etching cycle including three etching steps. The passivation layer helps to protect the mask layer 131 and control the feature size. The anisotropic plasma etching process 143 with low etching selectivity reduces scattered ions/radicals to reduce asymmetric etching, thereby avoiding the bowing issue. The high directionality of the anisotropic plasma etching process 143 ensures that the desired depth of the opening 132 is achieved. Since the bowing condition may interfere with formation of vias 165 formed subsequently to connect to backside power rails, the disclosed embodiments reduce device failure and improve production yield.

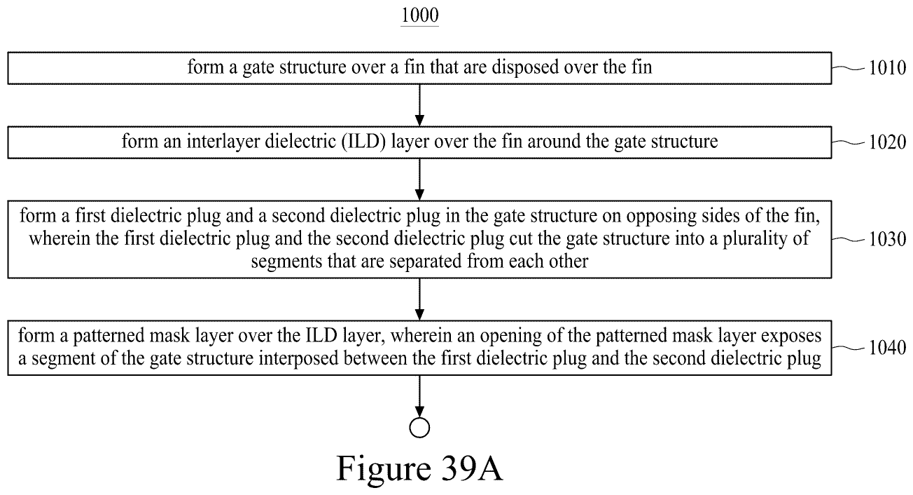

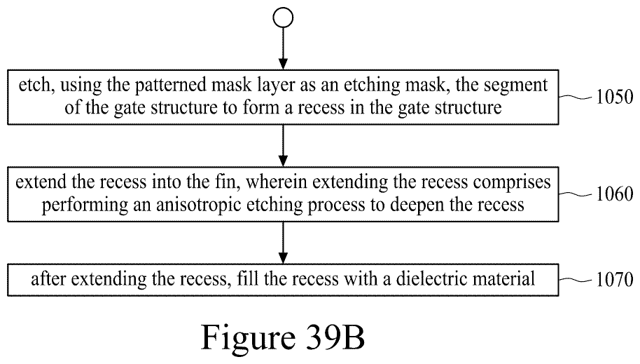

FIGS. 39A and 39B together illustrate a flow chart of a method 1000 of forming a semiconductor device, in accordance with some embodiments. It should be understood that the embodiment method shown in FIGS. 39A and 39B is merely an example of many possible embodiment methods. One of ordinary skill in the art would recognize many variations, alternatives, and modifications. For example, various steps as illustrated in FIGS. 39A and 39B may be added, removed, replaced, rearranged, or repeated.

Referring to FIGS. 39A and 39B, at block 1010, a gate structure is formed over a fin that protrudes above a substrate. At block 1020, an interlayer dielectric (ILD) layer is formed over the fin around the gate structure. At block 1030, a first dielectric plug and a second dielectric plug are formed in the gate structure on opposing sides of the fin, wherein the first dielectric plug and the second dielectric plug cut the gate structure into a plurality of segments that are separated from each other. At block 1040, a patterned mask layer is formed over the ILD layer, wherein an opening of the patterned mask layer exposes a segment of the gate structure interposed between the first dielectric plug and the second dielectric plug. At block 1050, using the patterned mask layer as an etching mask, the segment of the gate structure is etched to form a recess in the gate structure. At block 1060, the recess is extended into the fin, wherein extending the recess comprises performing an anisotropic etching process to deepen the recess. At block 1070, after extending the recess, the recess is filled with a dielectric material.

In an embodiment, a method of forming a semiconductor device includes: forming a first fin, a second fin, and a third fin that protrude above a substrate and extend parallel to each other, wherein the third fin is between the first fin and the second fin; forming a gate structure over the first fin, the second fin, and the third fin; forming gate spacers along opposing sidewalls of the gate structure; forming an interlayer dielectric (ILD) layer over the first fin, the second fin, and the third fin and around the gate structure; forming, in the gate structure, a first dielectric plug and a second dielectric plug that separate the gate structure into a plurality of segments, wherein the first dielectric plug is formed between the first fin and the third fin, and the second dielectric plug is formed between the third fin and the second fin; forming a patterned mask layer over the ILD layer, wherein a first opening of the patterned mask layer exposes a first segment of the gate structure disposed between the first dielectric plug and the second dielectric plug; performing a first etching process using the patterned mask layer as an etching mask, wherein the first etching process recesses the first segment of the gate structure and forms a recess between the gate spacers; after performing the first etching process, performing a second etching process different from the first etching process to deepen the recess, wherein after the second etching process is finished, the recess extends into the substrate; and after performing the second etching process, forming a dielectric structure in the recess. In an embodiment, in a top view, there is a lateral offset between a first center axis of the first opening and a longitudinal center axis of the gate structure, wherein the first center axis of the first opening and the longitudinal center axis of the gate structure extend in parallel. In an embodiment, the lateral offset is between about 5% and about 33% of a width of the gate structure measured between the gate spacers. In an embodiment, forming the patterned mask layer comprises: forming a hard mask layer over the ILD layer; forming a photoresist layer over the hard mask layer; forming a second opening in the photoresist layer to form a patterned photoresist layer, wherein in the top view, a second center axis of the second opening is laterally shifted from the longitudinal center axis of the gate structure by a predetermined amount; and patterning the hard mask layer using the patterned photoresist layer to form the patterned mask layer, wherein the second opening of the patterned photoresist layer corresponds to the first opening of the patterned mask layer due to the patterning of the hard mask layer. In an embodiment, after the first etching process, a first sidewall of the gate spacers facing the gate structure is exposed to the recess, and a second opposing sidewall of the gate spacers facing the gate structure is covered by a remaining portion of the gate structure, wherein after the second etching process and before filling the recess, the first sidewall and the second opposing sidewall of the gate spacers are exposed to the recess. In an embodiment, an etching selectivity of the second etching process, calculated as a ratio between a first etch rate of the substrate and a second etch rate of the gate spacers, is between about 0.2 and about 5. In an embodiment, the second etching process is an anisotropic plasma etching process, wherein the method further comprises setting an amplitude of a bias voltage of the anisotropic plasma etching process between about 500 V and about 1200 V. In an embodiment, after the second etching process, a lower portion of the recess extends into the substrate, wherein sidewalls of the lower portion of the recess have a linear profile and intersect to form a V-shape. In an embodiment, the gate structure is a dummy gate structure, wherein the method further comprises, after filling the recess: removing the patterned mask layer; and replacing a second segment of the dummy gate structure and a third segment of the dummy gate structure with a first replacement gate structure and a second replacement gate structure, respectively, wherein the second segment of the dummy gate structure overlies the first fin, and the third segment of the dummy gate structure overlies the second fin. In an embodiment, the dielectric structure has a multi-layer structure, wherein forming the dielectric structure comprises: forming a first dielectric material along sidewalls and a bottom of the recess; and after forming the first dielectric material, forming a second dielectric material different from the first dielectric material in the recess over the first dielectric material. In an embodiment, the method further comprises, after forming the dielectric structure: forming a front-side interconnect structure over and electrically coupled to the gate structure; bonding the front-side interconnect structure to a carrier; after the bonding, performing a backside thinning process to remove the substrate and portions of the first fin, the second fin, and the third fin; after the backside thinning process, forming a backside via that extends through the third fin and electrically coupled to a source/drain region adjacent to the gate structure; and after forming the backside via, forming a backside interconnect structure that is electrically coupled to the backside via. In an embodiment, the method further comprises, after performing the first etching process and before performing the second etching process: forming a passivation layer along sidewalls and a bottom of the recess; and after forming the passivation layer, removing the passivation layer from the bottom of the recess.

In an embodiment, a method of forming a semiconductor device includes: forming a gate structure over a fin that protrudes above a substrate; forming an interlayer dielectric (ILD) layer over the fin around the gate structure; forming a first dielectric plug and a second dielectric plug in the gate structure on opposing sides of the fin, wherein the first dielectric plug and the second dielectric plug cut the gate structure into a plurality of segments that are separated from each other; forming a patterned mask layer over the ILD layer, wherein an opening of the patterned mask layer exposes a segment of the gate structure interposed between the first dielectric plug and the second dielectric plug; etching, using the patterned mask layer as an etching mask, the segment of the gate structure to form a recess in the gate structure; extending the recess into the fin, wherein extending the recess comprises performing an anisotropic etching process to deepen the recess; and after extending the recess, filling the recess with a dielectric material. In an embodiment, after extending the recess, a lower portion of the recess has slanted linear sidewalls, wherein a distance between the slanted linear sidewalls decreases as the recess extends toward the fin. In an embodiment, an etching selectivity of the anisotropic etching process is between about 0.2 and about 5, wherein the etching selectivity is computed as a ratio between a first etch rate of the substrate and a second etch rate of gate spacers of the gate structure. In an embodiment, extending the recess comprises performing a plurality of etching cycles using the patterned mask layer as the etching mask, wherein each of the plurality of etching cycles is performed by: lining sidewalls and a bottom of the recess with a passivation layer; after the lining, removing the passivation layer from the bottom of the recess; and after removing the passivation layer from the bottom of the recess, performing the anisotropic etching process to deepen the recess. In an embodiment, forming the patterned mask layer comprises forming the opening of the patterned mask layer to be laterally shifted from a longitudinal center axis of the gate structure by a predetermined distance.

In an embodiment, a method of forming a semiconductor device includes: forming a gate structure over a fin that protrudes above a substrate; forming an interlayer dielectric (ILD) layer over the fin around the gate structure; forming a first dielectric plug and a second dielectric plug in the gate structure on opposing sides of the fin, wherein the first dielectric plug and the second dielectric plug cut the gate structure into a plurality of discrete segments; forming a patterned mask layer over the ILD layer, wherein an opening of the patterned mask layer exposes a segment of the gate structure interposed between the first dielectric plug and the second dielectric plug, wherein the opening of the patterned mask layer is formed to be laterally shifted from the segment of the gate structure by a predetermined distance, wherein in a top view, there is a lateral offset between a longitudinal center axis of the gate structure and a center axis of the opening; etching, using the patterned mask layer as an etching mask, the segment of the gate structure to form a recess in the gate structure; extending the recess into the fin, where extending the recess comprises performing an anisotropic etching process to deepen the recess; and after extending the recess, filling the recess with a dielectric material. In an embodiment, after extending the recess and before filling the recess, an upper portion of the recess disposed between gate spacers of the gate structure has a uniform width, wherein a lower portion of the recess disposed between the upper portion of the recess and the substrate has slanted linear sidewalls, and a width of the lower portion of the recess decreases continuously as the lower portion of the recess extends toward the substrate. In an embodiment, the anisotropic etching process is an anisotropic plasma etching process, wherein an etching selectivity of the anisotropic etching process is between about 0.2 and about 5, wherein the etching selectivity is calculated as a ratio between an etch rate of the substrate and an etch rate of gate spacers of the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a gate structure over a fin that protrudes above a substrate;
forming gate spacers along opposing sidewalls of the gate structure;
forming an interlayer dielectric (ILD) layer over the fin and around the gate structure;
forming a patterned mask layer over the ILD layer, wherein an opening of the patterned mask layer exposes a segment of the gate structure, wherein there is a lateral offset between a longitudinal center axis of the gate structure and a center axis of the opening;
etching, using the patterned mask layer as an etching mask, the segment of the gate structure to form a recess in the gate structure, wherein etching the segment of the gate structure removes an upper portion of the gate structure, wherein a lower portion of the gate structure remains after etching the segment of the gate structure;
after the etching, extending the recess into the fin; and
after extending the recess, filling the recess with a dielectric material.

2. The method of claim 1, wherein the lateral offset is between about 10% and about 33% of a width of the gate structure measured between the gate spacers.

3. The method of claim 1, further comprising, before forming the patterned mask layer, forming a first dielectric plug and a second dielectric plug in the gate structure, wherein the first dielectric plug and the second dielectric plug separate the gate structure into a plurality of segments that are separated from each other.

4. The method of claim 3, wherein the segment of the gate structure exposed by the opening of the patterned mask layer is disposed laterally between the first dielectric plug and the second dielectric plug along a first direction, and is disposed laterally between the gate spacers along a second direction perpendicular to the first direction.

5. The method of claim 4, wherein etching the segment of the gate structure comprises performing a first anisotropic etching process using the patterned mask layer as the etching mask.

6. The method of claim 4, wherein etching the segment of the gate structure comprises performing a wet etching process.

7. The method of claim 3, wherein the gate spacers comprise a first gate spacer and a second gate spacer, wherein after etching the segment of the gate structure, the recess has an asymmetric profile relative to the longitudinal center axis of the gate structure such that a first sidewall of the first gate spacer facing the gate structure is exposed to the recess, and a second sidewall of the second gate spacer facing the gate structure is covered by a remaining portion of the gate structure.

8. The method of claim 7, wherein extending the recess comprises performing a plurality of etching cycles to extend the recess into the fin, wherein each of the plurality of etching cycles is performed by:
lining sidewalls and a bottom of the recess with a passivation layer;
after the lining, removing the passivation layer from the bottom of the recess; and
after removing the passivation layer from the bottom of the recess, performing a second anisotropic etching process to deepen the recess.

9. The method of claim 8, wherein an etching selectivity of the second anisotropic etching process is between about 0.2 and about 5, wherein the etching selectivity is calculated as a ratio between an etch rate of the substrate and an etch rate of the gate spacers.

10. The method of claim 9, wherein the second anisotropic etching process is an anisotropic plasma etching process, wherein the anisotropic plasma etching process is performed with a bias voltage having an amplitude between about 500 V and about 1200 V.

11. The method of claim 8, wherein after the plurality of etching cycles are finished, the second sidewall of the second gate spacer is exposed to the recess.

12. The method of claim 1, further comprising, after filling the recess:
forming a front-side interconnect structure at a first side of the ILD layer;
bonding the front-side interconnect structure to a carrier;
after the bonding, performing a backside thinning process to remove the substrate; and
after the backside thinning process, forming a backside interconnect structure at a second opposing side of the ILD layer.

13. A method of forming a semiconductor device, the method comprising:
forming a gate structure over a fin;
forming a first dielectric plug and a second dielectric plug in the gate structure, wherein the first dielectric plug and the second dielectric plug separate the gate structure into discrete segments;
forming a recess in a segment of the gate structure disposed between the first dielectric plug and the second dielectric plug by performing a first etching process, wherein after performing the first etching process, a lower portion of the segment of the gate structure remains under the recess;
extending the recess into the fin by performing one or more etching cycles, wherein each of the one or more etching cycles is performed by:
lining sidewalls and a bottom of the recess with a passivation layer;
after the lining, removing the passivation layer from the bottom of the recess; and
after removing the passivation layer from the bottom of the recess, performing a second etching process to deepen the recess; and
filling the extended recess with a dielectric material.

14. The method of claim 13, wherein the recess is formed to be off-center with respect to a longitudinal center axis of the gate structure such that after forming the recess in the segment of the gate structure, a first sidewall of a first gate spacer facing the gate structure is exposed to the recess, and a second sidewall of a second gate spacer facing the gate structure is covered by a remaining portion of the gate structure, wherein the first gate spacer and the second gate spacer extend along a first sidewall of the gate structure and a second opposing sidewall of the gate structure, respectively.

15. The method of claim 13, wherein the second etching process is an anisotropic etching process having an etching selectivity between about 0.2 and about 5, wherein the etching selectivity is calculated as a ratio between an etch rate of the fin and an etch rate of a gate spacer of the gate structure.

16. The method of claim 15, wherein the second etching process is an anisotropic plasma etching process performed with a bias voltage having an amplitude between about 500 V and about 1200 V.

17. A method of forming a semiconductor device, the method comprising:
forming a channel layer over a substrate;
forming a gate structure around the channel layer;
forming gate spacers along sidewalls of the gate structure;
forming a dielectric layer over the substrate around the gate structure;
forming a first dielectric plug and a second dielectric plug in the gate structure that segment the gate structure into discrete segments;
recessing a segment of the gate structure disposed between the first dielectric plug and the second dielectric plug to form a recess in the segment of the gate structure;
deepening the recess into the substrate using one or more etching cycles, wherein each of the one or more etching cycles comprises:
forming a conformal passivation layer along sidewalls and a bottom of the recess;
removing the conformal passivation layer from the bottom of the recess; and
performing an anisotropic etching process to deepen the recess; and
after deepening the recess, filling the recess with a dielectric material.

18. The method of claim 17, wherein recessing the segment of the gate structure comprises:
forming a patterned mask layer over the dielectric layer, wherein an opening of the patterned mask layer exposes the segment of the gate structure, wherein there is a lateral offset between a longitudinal center axis of the gate structure and a center axis of the opening; and
performing an etching process using the patterned mask layer as an etching mask to recess the segment of the gate structure.

19. The method of claim 18, wherein the first dielectric plug and the second dielectric plug are formed to extend through the gate structure and into isolation regions under the gate structure.

20. The method of claim 18, wherein the anisotropic etching process is an anisotropic plasma etching process having an etching selectivity between about 0.2 and about 5, wherein the etching selectivity is calculated as a ratio between an etch rate of the substrate and an etch rate of the gate spacers, wherein the anisotropic plasma etching process is performed with a bias voltage having an amplitude between about 500 V and about 1200 V.
